(19) United States
(12) Patent Application Publication
(10) Pub. No.: US 2025/0048639 A1
(43) Pub. Date: Feb. 6, 2025

(54) NON-VOLATILE MEMORY DEVICE

(71) Applicant: Samsung Electronics Co., Ltd., Suwon-si (KR)

(72) Inventors: Hakseon Kim, Suwon-si (KR); Kangoh Yun, Suwon-si (KR); Dongjin Lee, Suwon-si (KR); Youngrok Kim, Suwon-si (KR); Ryoongbin Lee, Suwon-si (KR); Jaeduk Lee, Suwon-si (KR)

(21) Appl. No.: 18/653,301

(22) Filed: May 2, 2024

(30) Foreign Application Priority Data
Aug. 2, 2023 (KR) 10-2023-0101123

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A non-volatile memory device includes a peripheral circuit and a memory cell array that are sequentially stacked. The peripheral circuit includes, a device isolation layer defining an active region within a substrate, a first gate electrode extending in a first horizontal direction on the active region, an insulating pattern in a first recess and a second recess spaced apart in a second horizontal direction within the active region on opposing sides of the first gate electrode, a first low concentration doped region along an outer wall of the first recess, a second low concentration doped region along an outer wall of the second recess, a first source/drain region buried in the first low concentration doped region, and a second source/drain region buried in the second low concentration doped region.

### CROSS-REFERENCE TO RELATED APPLICATION

This application claims priority under 35 U.S.C. § 119 to Korean Patent Application No. 10-2023-0101123, filed on Aug. 2, 2023, in the Korean Intellectual Property Office, the disclosure of which is incorporated by reference herein in its entirety.

### FIELD

The inventive concept relates to a non-volatile memory device and an electronic system including the same, and more specifically, to a non-volatile memory device including a transistor and an electronic system including the non-volatile memory device.

### BACKGROUND

Non-volatile memory devices, such as flash memory devices, that may be capable of storing high-capacity data have been proposed for use in electronic systems to meet data storage needs. Flash memory devices may include transistors, such as high-voltage transistors.

### SUMMARY

The inventive concept provides a non-volatile memory device with improved device performance and reliability.

The inventive concept provides an electronic system with improved device performance and reliability.

Technical problems to be solved by the inventive concept are not limited to the problems mentioned above, and other problems not mentioned will be clearly understood by those skilled in the art from the description below.

According to another aspect of the inventive concept, there is provided a non-volatile memory device. The non-volatile memory device includes a peripheral circuit and a memory cell array that are sequentially stacked, wherein the peripheral circuit includes a substrate including a device isolation layer in a device isolation trench defining an active region, a first gate electrode extending in a first horizontal direction on the active region of the substrate, an insulating pattern in a first recess and a second recess spaced apart in a second horizontal direction intersecting the first horizontal direction within the active region on opposing sides of the first gate electrode, a first low concentration doped region within the substrate and extending along an outer wall of the first recess, a second low concentration doped region within the substrate and extending along an outer wall of the second recess, a first source/drain region buried in the first low concentration doped region between the first recess and the device isolation trench in the second horizontal direction, and a second source/drain region buried in the second low concentration doped region between the second recess and the device isolation trench in the second horizontal direction, where a depth of each of the first recess and the second recess is 400 nm or less, and a depth of the device isolation trench is 1000 nm or more but is less than a thickness of the substrate in a vertical direction.

According to another aspect of the inventive concept, there is provided a non-volatile memory device. The non-volatile memory device includes a peripheral circuit including a plurality of transistors, wherein the plurality of transistors include a pair of gate electrodes extending in a first horizontal direction on an active region defined by a device isolation layer in a substrate and spaced apart from each other in a second horizontal direction intersecting the first horizontal direction, a plurality of low concentration doped regions respectively extending in the substrate along outer walls of a plurality of recesses disposed on opposing sides of each of the pair of gate electrodes, and a plurality of source/drain regions buried in the plurality of low concentration doped regions, where the device isolation layer is disposed in a device isolation trench extending around the pair of gate electrodes, a depth of each of the plurality of recesses is 400 nm or less, and a depth of the device isolation trench is 1000 nm or more but is less than a thickness of the substrate in a vertical direction.

According to another aspect of the inventive concept, there is provided a non-volatile memory device. The non-volatile memory device includes a peripheral circuit including a plurality of transistors provided on a substrate, and a memory cell array configured to be controlled by the peripheral circuit, wherein the plurality of transistors include a first polysilicon electrode and a second polysilicon electrode extending in a first horizontal direction on an active region defined by a device isolation layer in the substrate and spaced apart from each other in a second horizontal direction intersecting the first horizontal direction, a plurality of low concentration doped regions respectively provided in the substrate along outer walls of a plurality of recesses on opposing sides of each of the first polysilicon electrode and the second polysilicon electrode, and a plurality of source/drain regions buried in the plurality of low concentration doped regions, the device isolation layer is in a device isolation trench extending around the first and second polysilicon electrodes, the plurality of low concentration doped regions include a first low concentration doped region between the device isolation trench and the first polysilicon electrode, a second low concentration doped region between the first polysilicon electrode and the second polysilicon electrode, and a third low concentration doped region spaced apart from the second low concentration doped region with the second polysilicon electrode therebetween, where the plurality of recesses include a first recess, a second recess, a third recess, and a fourth recess spaced apart from each other in the second horizontal direction, the plurality of source/drain regions include a first source/drain region buried in the first low concentration doped region and spaced apart from the first polysilicon electrode with the first recess therebetween, a second source/drain region buried in the second low concentration doped region and spaced apart from the first polysilicon electrode with the second recess therebetween and spaced apart from the second polysilicon electrode with the third recess therebetween, and a third source/drain region buried in the third low concentration doped region and spaced apart from the second polysilicon electrode with the fourth recess therebetween, where a depth of each of the plurality of recesses is 400 nm or less, and a depth of the device isolation trench is 1000 nm or more but is less than a thickness of the substrate in a vertical direction.

### BRIEF DESCRIPTION OF THE DRAWINGS

Embodiments will be more clearly understood from the following detailed description taken in conjunction with the accompanying drawings in which:

FIG. 1 is a block diagram of a non-volatile memory device according to an embodiment;

FIG. 2 is a schematic perspective view of a non-volatile memory device according to an embodiment;

FIG. 3 is an equivalent circuit diagram of a memory cell array of a non-volatile memory device according to an embodiment;

FIG. 4 is a schematic plan view of a partial region of a non-volatile memory device according to an embodiment;

FIGS. 5, 6, and 7 are detailed diagrams illustrating a non-volatile memory device according to an embodiment;

FIGS. 8A and 8B are plan and cross-sectional views illustrating a transistor included in a non-volatile memory device according to an embodiment;

FIGS. 9A and 9B are plan and cross-sectional views illustrating a transistor included in a non-volatile memory device according to another embodiment;

FIGS. 10A and 10B are plan and cross-sectional views illustrating a transistor included in a non-volatile memory device according to another embodiment;

FIGS. 11A, 11B, 11C, 11D, 11E, 11F, and 11G are cross-sectional views illustrating a method of manufacturing a transistor included in a non-volatile memory device according to an embodiment;

FIG. 12 is a cross-sectional view illustrating a non-volatile memory device according to an embodiment;

FIG. 13 is a diagram schematically illustrating an electronic system including a non-volatile memory device according to an embodiment;

FIG. 14 is a perspective view schematically illustrating an electronic system including a non-volatile memory device according to an embodiment; and

FIG. 15 is a cross-sectional view schematically illustrating a semiconductor package according to an embodiment.

### DETAILED DESCRIPTION OF EMBODIMENTS

Hereinafter, embodiments of the inventive concept will be described in detail with reference to the accompanying drawings. However, the inventive concept does not have to be configured as limited to the embodiments described below and may be embodied in various other forms. The following embodiments are not provided to fully complete the inventive concept, but rather are provided to fully convey the scope of the inventive concept to those skilled in the art. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly on” or “in direct contact” or “directly connected,” no intervening components or layers are present.

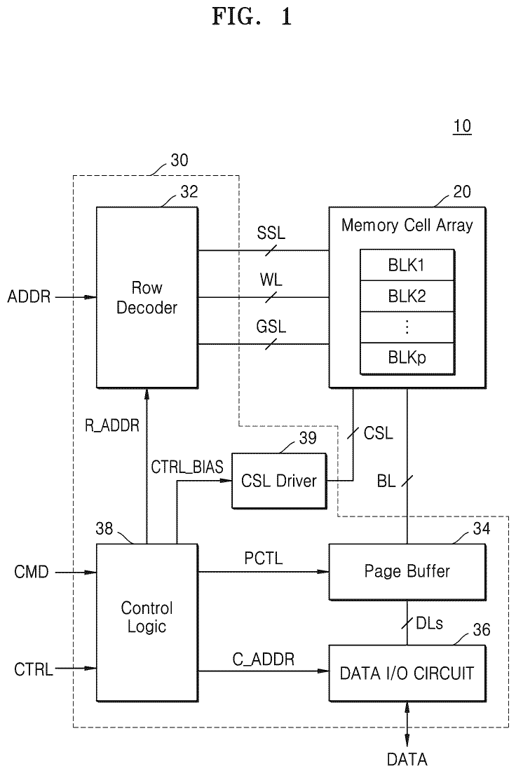

FIG. 1 is a block diagram of a non-volatile memory device 10 according to an embodiment.

Specifically, the non-volatile memory device 10 may include a memory cell array 20 and a peripheral circuit 30. The memory cell array 20 may be controlled by the peripheral circuit 30. The memory cell array 20 may include a plurality of memory cell blocks BLK1, BLK2, . . . , BLKp. Each of the plurality of memory cell blocks BLK1, BLK2, . . . , BLKp may include a plurality of memory cells. The memory cell blocks BLK1, BLK2, . . . , BLKp may be connected to the peripheral circuit 30 through one or more bit lines BL, word lines WL, string selection lines SSL, and ground selection lines GSL.

The peripheral circuit 30 may include a row decoder 32, a page buffer 34, a data input/output (I/O) circuit 36, a control logic 38, and a common source line (CSL) driver 39. The peripheral circuit 30 may further include various circuits such as a voltage generation circuit generating various voltages necessary for the operation of the non-volatile memory device 10, an error correction circuit correcting errors in data readout from the memory cell array 20, an input/output interface, etc.

In some embodiments, each component constituting the peripheral circuit 30 may include a plurality of transistors, for example, MOS (metal-oxide-semiconductor) transistors. In some embodiments, each component constituting the peripheral circuit 30 may include a plurality of transistors, for example, high voltage transistors. In some embodiments, high voltage transistors may refer to transistors having a breakdown voltage of 5 V to 10 V, or 10 V or more.

The memory cell array 20 may be connected to the row decoder 32 through the word line WL, the string selection line SSL, and the ground selection line GSL, and may be connected to the page buffer 34 through the bit line BL. In the memory cell array 20, the plurality of memory cells included in each of the plurality of memory cell blocks BLK1, BLK2, . . . , BLKp may be flash memory cells. The memory cell array 20 may include a three-dimensional (3D) memory cell array. The 3D memory cell array may include a plurality of NAND strings. Each of the plurality of NAND strings may include a plurality of memory cells respectively connected to a plurality of vertically stacked word lines WL.

The peripheral circuit 30 may receive an address ADDR, a command CMD, and a control signal CTRL from the outside of the non-volatile memory device 10, and may transmit/receive data DATA to and from an apparatus outside the non-volatile memory device 10. The row decoder 32 may select at least one of the plurality of memory cell blocks BLK1, BLK2, . . . , BLKp in response to the address ADDR from the outside, and may select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation to apply a voltage according to the data DATA to be stored in the memory cell array 20 to the bit line BL, and may operate as a sense amplifier during a read operation to sense the data DATA stored in the memory cell array 20. The page buffer 34 may operate according to a control signal PCTL provided from the control logic 38.

The data I/O circuit 36 may be connected to the page buffer 34 through a plurality of data lines DLs. The data I/O circuit 36 may receive data DATA from a memory controller (not shown) during a program operation, and may provide the program data DATA to the page buffer 34 based on a column address C_ADDR provided from the control logic 38. The data I/O circuit 36 may provide the read data DATA stored in the page buffer 34 to the memory controller based on the column address C_ADDR provided from the control logic 38 during a read operation.

The data I/O circuit 36 may transmit an input address or command to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide the column address C_ADDR to the data I/O circuit 36. The control logic 38 may generate various internal control signals used in the non-volatile memory device 10 in response to the control signal CTRL. For example, the control logic 38 may adjust the voltage level provided to the word line WL and the bit line BL when a memory operation such as a program operation or an erase operation is performed.

The common source line driver 39 may be connected to the memory cell array 20 through a common source line CSL. The common source line driver 39 may apply a common source voltage (e.g., a power supply voltage) or a ground voltage to the common source line CSL based on a bias signal CTRL_BIAS of the control logic 38.

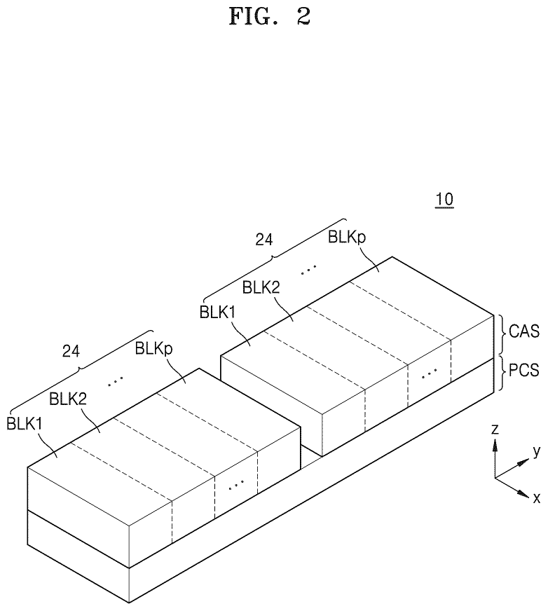

FIG. 2 is a schematic perspective view of the non-volatile memory device 10 according to an embodiment.

Specifically, the non-volatile memory device 10 may include a cell array structure CAS and a peripheral circuit structure PCS overlapping each other in a vertical direction (Z direction and third direction). Components or layers described with reference to “overlap” in a particular direction may be at least partially obstructed by one another when viewed along a line extending in the particular direction or in a plane perpendicular to the particular direction. The cell array structure CAS may include the memory cell array 20 of FIG. 1.

In some embodiments, the peripheral circuit structure PCS may include a plurality of transistors, for example, MOS transistors. In some embodiments, the peripheral circuit structure PCS may include a plurality of transistors, for example, high voltage transistors. In some embodiments, high voltage transistors may refer to transistors having a breakdown voltage of 5 V to 10 V or 10 V or more. The peripheral circuit structure PCS may include the peripheral circuit 30 of FIG. 1.

The cell array structure CAS may include a plurality of tiles 24. Each of the tiles 24 may include the plurality of memory cell blocks BLK1, BLK2, . . . , BLKp. Each of the memory cell blocks BLK1, BLK2, . . . , BLKp may include a plurality of 3D arranged memory cells.

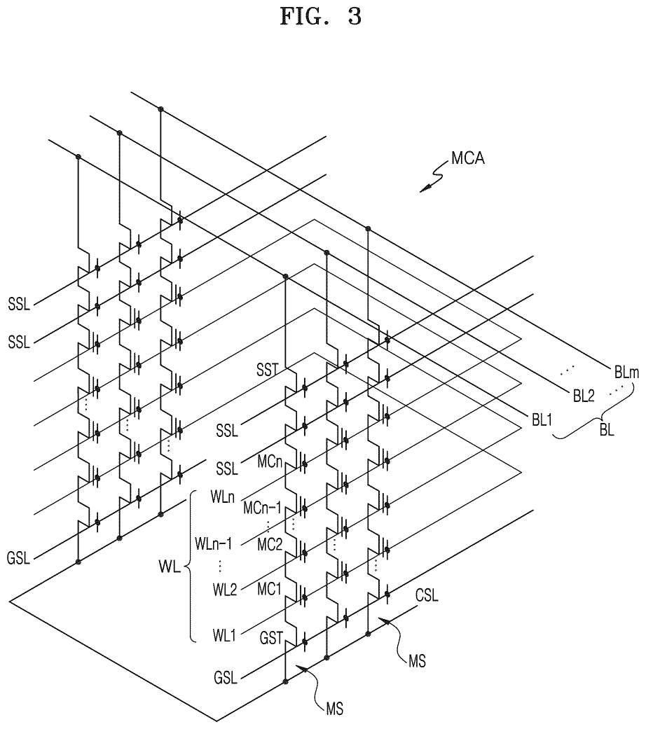

FIG. 3 is an equivalent circuit diagram of a memory cell array MCA of a non-volatile memory device according to an embodiment

Specifically, FIG. 3 is the equivalent circuit diagram of a vertical NAND flash memory device having a vertical channel structure. Each of the memory cell blocks BLK1, BLK2, . . . , BLKp of FIGS. 1 and 2 may include the memory cell array MCA having a circuit configuration illustrated in FIG. 3.

The memory cell array MCA may include a plurality of memory cell strings MS. The memory cell array MCA may include a plurality of bit lines BL or BL1, BL2, . . . , BLm, a plurality of word lines WL or WL1, WL2, . . . , WLn−1, WLn, at least one string selection line SSL, at least one ground selection line GSL, and the common source line CSL.

The plurality of memory cell strings MS may be formed between the plurality of bit lines BL and the common source lines CSL. FIG. 3 illustrates that each of the plurality of memory cell strings MS includes one ground selection line GSL and two string selection lines SSL, the inventive concept is not limited thereto. For example, each of the plurality of memory cell strings MS may include one string selection line SSL.

Each of the plurality of memory cell strings MS may include a string select transistor SST, a ground select transistor GST, and a plurality of memory cell transistors MC1, MC2, . . . , MCn−1, MCn. A drain region of the string select transistor SST may be connected to the bit line BL, and a source region of the ground select transistor GST may be connected to the common source line CSL. The common source line CSL may be a region to which source regions of the plurality of ground selection transistors GST are commonly connected.

The string select transistor SST may be connected to the string selection line SSL, and the ground select transistor GST may be connected to the ground selection line GSL. The plurality of memory cell transistors MC1, MC2, . . . , MCn−1, MCn may be respectively connected to a plurality of word lines WL.

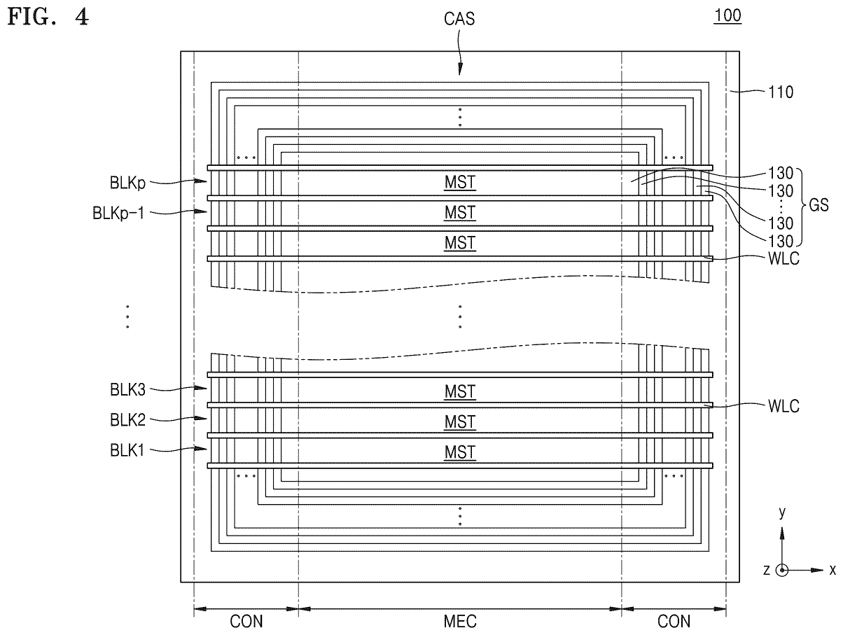

FIG. 4 is a schematic plan view of a partial region of a non-volatile memory device 100 according to an embodiment.

Specifically, the cell array structure CAS of the non-volatile memory device 100 may include an upper substrate 110 and the plurality of memory cell blocks BLK1, BLK2, . . . , BLKp disposed on the upper substrate 110.

The peripheral circuit structure PCS as shown in FIG. 2 may be disposed on a lower portion of the upper substrate 110. The plurality of memory cell blocks BLK1, BLK2, . . . , BLKp may overlap the peripheral circuit structure PCS in the vertical direction (Z direction and third direction) with the upper substrate 110 disposed therebetween. The peripheral circuit structure PCS disposed on the lower portion of the upper substrate 110 may include the peripheral circuit 30 of FIG. 1.

The cell array structure CAS may include a memory cell region MEC and connection regions CON disposed on both sides of the memory cell region MEC in a first horizontal direction (X direction). Each of the plurality of memory cell blocks BLK1, BLK2, . . . , BLKp may include a memory stack structure MST extending in the first horizontal direction (X direction) across the memory cell region MEC and the connection region CON.

The memory stack structure MST may include a plurality of gate lines 130 stacked to overlap each other in the vertical direction (Z direction) in the memory cell region MEC and the connection region CON on the upper substrate 110. The plurality of gate lines 130 may respectively constitute a gate stack GS in a plurality of memory stack structures MST.

The plurality of gate lines 130 may respectively constitute the ground selection line GSL, the plurality of word lines WL, and the string selection line SSL of FIG. 3 in the plurality of memory stack structures MST. Areas of the plurality of gate lines 130 in an X-Y plane may gradually decrease as the distance from the upper substrate 110 increases. A central part of each of the plurality of gate lines 130 overlapping each other in the vertical direction (Z direction and third direction) may constitute the memory cell region MEC, and an edge part of each of the plurality of gate lines 130 may constitute the connection region CON.

A plurality of word line cut structures WLC extending in the first horizontal direction (X direction) from the memory cell region MEC and the connection region CON may be disposed on the upper substrate 110. The plurality of word line cut structures WLC may be spaced apart from each other in a second horizontal direction (Y direction). The plurality of memory cell blocks BLK1, BLK2, . . . , BLKp may be disposed between each of the plurality of word line cut structures WLC.

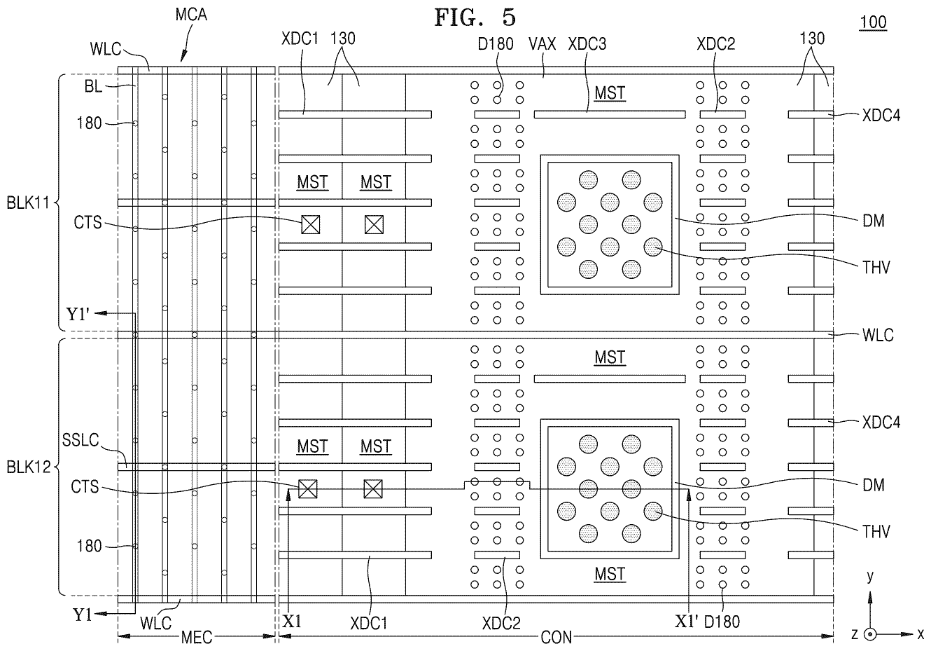

FIGS. 5 to 7 are detailed diagrams illustrating the non-volatile memory device 100 according to an embodiment.

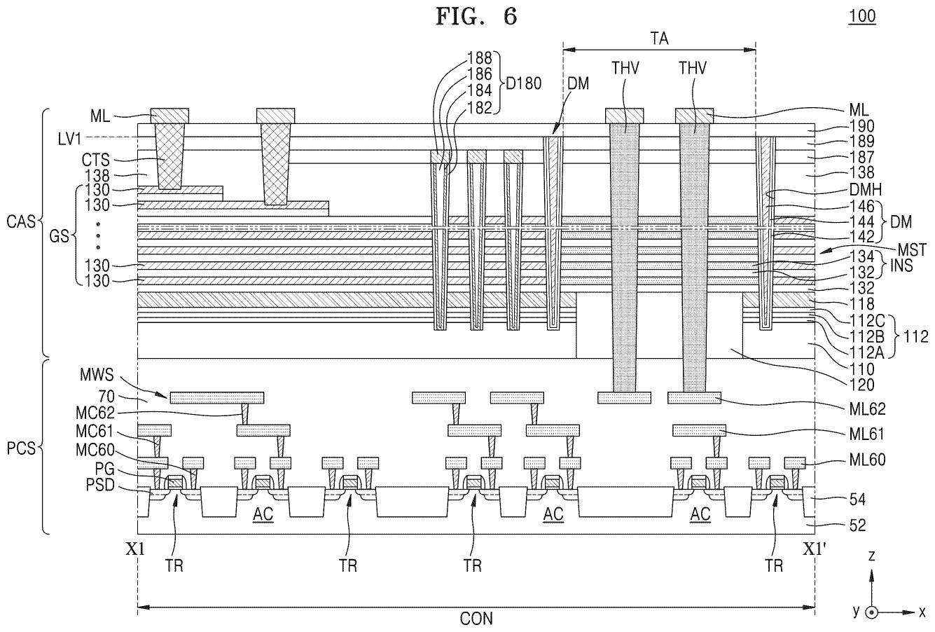

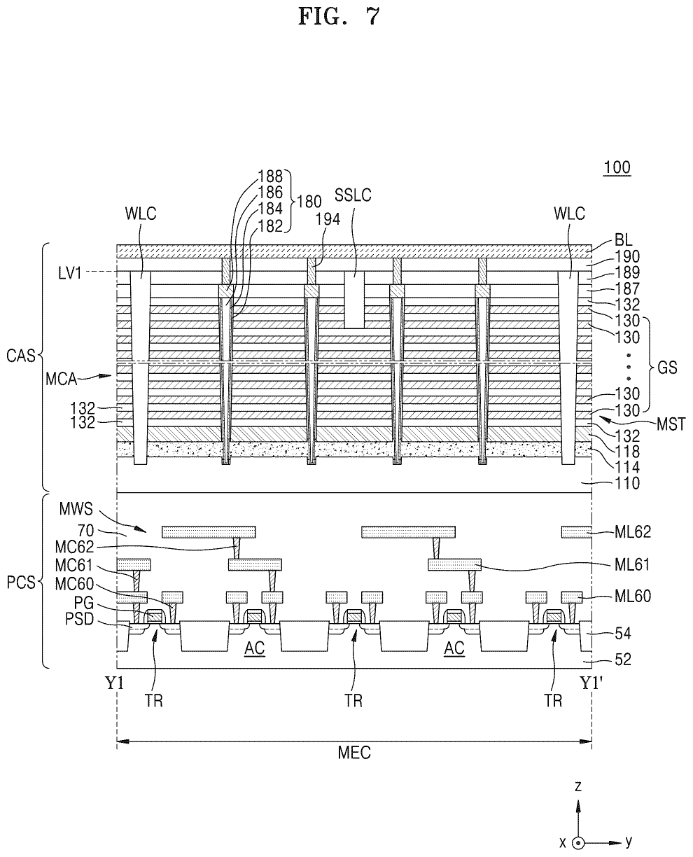

Specifically, FIG. 5 is a plan view of some components of memory cell blocks BLK11 and BLK12 that may be included in the plurality of memory cell blocks BLK1, BLK2, . . . , BLKp of FIG. 4. FIG. 6 is an enlarged cross-sectional view of some components taken along line X1-X1′ of FIG. 5. FIG. 7 is an enlarged cross-sectional view of some components taken along line Y1-Y1′ of FIG. 5.

Referring to FIGS. 5 to 7, the non-volatile memory device 100 may include the peripheral circuit structure PCS and the cell array structure CAS disposed on the peripheral circuit structure PCS and overlapping the peripheral circuit structure PCS in the vertical direction (third direction) as shown in FIG. 2.

The cell array structure CAS may include an upper substrate 110, an insulating plate 112, a first conductive plate 114, a second conductive plate 118, and the memory stack structure MST. In the memory cell region MEC of the cell array structure CAS, the first conductive plate 114, the second conductive plate 118, and the memory stack structure MST may be sequentially stacked on the upper substrate 110. In the connection region CON of the cell array structure CAS, the insulating plate 112, the second conductive plate 118, and the memory stack structure MST may be sequentially stacked on the upper substrate 110.

Each of the first conductive plate 114 and the second conductive plate 118 may function as the common source line CSL of FIG. 3. Each of the first conductive plate 114 and the second conductive plate 118 may function as a source region for supplying current to vertical memory cells included in the cell array structure CAS.

In some embodiments, the upper substrate 110 may include a semiconductor material such as polysilicon. Each of the first conductive plate 114 and the second conductive plate 118 may include a doped polysilicon layer, a metal layer, or a combination thereof. The metal layer may include tungsten (W), but is not limited thereto.

The memory stack structure MST may include the gate stack 130. The gate stack 130 may include the plurality of gate lines 130 extending parallel to each other in the first horizontal direction (X direction) and overlapping each other in the vertical direction (Z direction). Each of the plurality of gate lines 130 may include metal, metal silicide, a semiconductor doped with impurities, or a combination thereof. For example, each of the plurality of gate lines 130 may include a metal such as tungsten, nickel, cobalt, or tantalum, a metal silicide such as tungsten silicide, nickel silicide, cobalt silicide, or tantalum silicide, doped polysilicon, or a combination thereof.

An insulating layer 132 may be disposed between the second conductive plate 118 and the plurality of gate lines 130 and between each of the plurality of gate lines 130. An uppermost gate line 130 among the plurality of gate lines 130 may be covered with the insulating layer 132. The insulating layer 132 may include silicon oxide.

The plurality of word line cut structures WLC may extend long in the first horizontal direction (X direction) on the upper substrate 110 in the memory cell region MEC and the connection region CON. A width of each of the plurality of gate lines 130 included in the memory cell blocks BLK11 and BLK12 in the second horizontal direction (Y direction) may be limited by the plurality of word line cut structures WLC.

Each of the plurality of word line cut structures WLC may include an insulating structure. In some embodiments, the insulating structure may include silicon oxide, silicon nitride, silicon oxynitride, or a low-k material. For example, the insulating structure may include a silicon oxide layer, a silicon nitride layer, a SiON layer, a SiOCN layer, a SiCN layer, or a combination thereof. In some embodiments, at least a part of the insulating structure may include an air gap or void. As used herein, the term “air” may refer to the atmosphere or other gases that may be present during a manufacturing process.

The plurality of gate lines 130 constituting one gate stack GS may be stacked to overlap each other in the vertical direction (Z direction) on the second conductive plate 118 between two adjacent word line cut structures WLC. The plurality of gate lines 130 constituting one gate stack GS may include the ground selection line GSL, the plurality of word lines WL, and the string selection line SSL of FIG. 3.

As illustrated in FIG. 7, in the plurality of gate lines 130, the upper two gate lines 130 may be separated in the second horizontal direction (Y direction) with a string selection line cut structure SSLC disposed therebetween. Each of the two gate lines 130 separated from each other with the string selection line cut structure SSLC disposed therebetween may constitute the string selection line SSL.

FIG. 7 illustrates that one string selection line cut structure SSLC is formed in one gate stack GS, but the inventive concept is not limited to that shown in FIG. 7. For example, at least two string selection line cut structures SSLC may be formed on one gate stack GS. The string selection line cut structure SSLC may be filled with an insulating layer. In some embodiments, the string selection line cut structure SSLC may include an insulating layer including an oxide layer, a nitride layer, or a combination thereof. In some embodiments, at least a part of the string selection line cut structure SSLC may include an air gap.

As illustrated in FIGS. 5 and 7, a plurality of channel structures 180 may penetrate the plurality of gate lines 130, the plurality of insulating layers 132, the second conductive plate 118, and the first conductive plate 114 and extend in the vertical direction (Z direction) on the upper substrate 110 in the memory cell region MEC. The plurality of channel structures 180 may be arranged spaced apart from each other with a certain gap therebetween in the first horizontal direction (X direction) and the second horizontal direction (Y direction). Each of the plurality of channel structures 180 may include a gate dielectric layer 182, a channel region 184, a filling insulating layer 186, and a drain region 188.

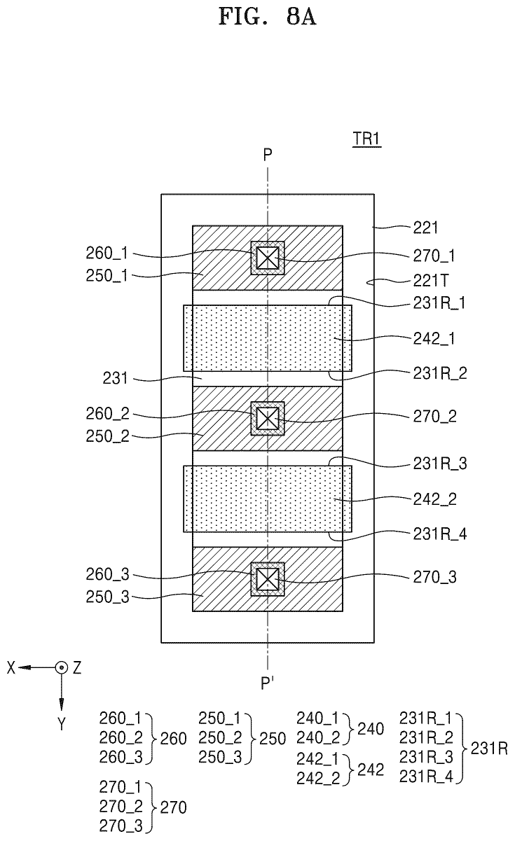

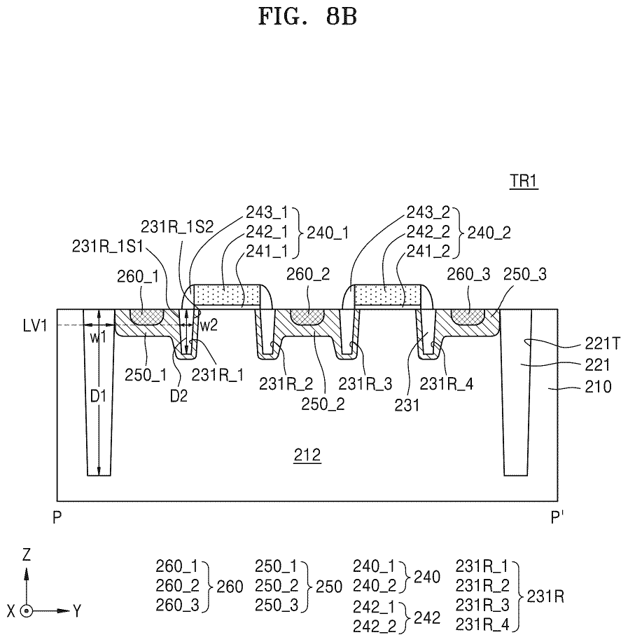

FIGS. 8A and 8B are plan and cross-sectional views illustrating a transistor TR1 included in a non-volatile memory device according to an embodiment.

Specifically, FIGS. 8A and 8B may be diagrams illustrating the transistor TR included in the non-volatile memory devices 10 and 100 described above. FIGS. 8A and 8B may illustrate one transistor TR1 among the transistors TR included in the peripheral circuit (e.g., 30 in FIG. 1) in the peripheral circuit structure PCS of the non-volatile memory devices 10 and 100 described above.

FIG. 8A is the plan view of the transistor TR1 according to an embodiment, and FIG. 8B is the cross-sectional view taken along line P-P′ of FIG. 8A.

Referring to FIGS. 8A and 8B, a device isolation layer 221 may be disposed on a substrate 210. At this time, an active region 212 may be defined in the substrate 210 by the device isolation layer 221. The device isolation layer 221 may serve to prevent electrons inside the active region 212 from flowing to other transistors or devices. According to an embodiment, the device isolation layer 221 may include silicon oxide. The device isolation layer 221 may be disposed in a device isolation trench 221T.

In some embodiments, a pair of gate structures 240 may be spaced apart from each other in the second horizontal direction (Y direction) on the active region 212 defined by the device isolation layer 221. As shown in FIG. 8B, a first gate structure 240_1 may be disposed on the left in the second horizontal direction (Y direction), and the second gate structure 240_2 may be disposed on the right in the second horizontal direction (Y direction).

In some embodiments, the first gate structure 240_1 may include a first gate electrode 242_1 extending in a first horizontal direction (X direction), a gate dielectric layer 241_1 disposed between the first gate electrode 242_1 and the substrate 210, and a first gate spacer 243_1 disposed on both (e.g., opposing) sides of the first gate electrode 242_1. Likewise, the second gate structure 240_2 may include a second gate electrode 242_2 extending in the first horizontal direction (X direction), a second gate dielectric layer 241_2 disposed between the second gate electrode 242_2 and the substrate 210, and a second gate spacer 243_2 disposed on both sides of the second gate electrode 242_2.

In some embodiments, the first gate electrode 242_1 and the second gate electrode 242_2 may each include polysilicon.

In some embodiments, a plurality of recesses 231R may be disposed in the active region 212 on both sides of the pair of gate electrodes 242. In some embodiments, the plurality of recesses 231R may be arranged adjacent to both sides of the pair of gate electrodes 242 in the second horizontal direction (Y direction). In some embodiments, the plurality of recesses 231R may extend vertically downward (−Z direction) within the active region 212.

Specifically, a first recess 231R_1 and a second recess 231R_2 may be disposed in the active region 212 adjacent to both sides of the first gate electrode 242_1. The first recess 231R_1 and the second recess 231R_2 may be spaced apart from each other in the second horizontal direction (Y direction). Specifically, a third recess 231R_3 and a fourth recess 231R_4 may be disposed in the active region 212 adjacent to both sides of the second gate electrode 242_2. The third recess 231R_3 and the fourth recess 231R_4 may be spaced apart from each other in the second horizontal direction (Y direction).

In some embodiments, an insulating pattern 231 may be disposed within the plurality of recesses 231R. For example, the insulating pattern 231 may include silicon oxide.

In some embodiments, a plurality of low concentration doped regions 250 may be respectively disposed along outer walls of the plurality of recesses 231R. The plurality of low concentration doped regions 250 may include parts extending vertically downward (−Z direction) within the active region 212 respectively along the outer walls of the plurality of recesses 231R. The plurality of low concentration doped regions 250 may be configured to entirely surround the outer walls of the plurality of recesses 231R, respectively. Specifically, the plurality of low concentration doped regions 250 respectively surrounding the plurality of recesses 231R may be disposed within the active region 212 defined by the device isolation layer 221. Unless otherwise noted, the term “surrounding” or “filling” as may be used herein may not require completely surrounding or filling the described elements or layers, but may, for example, refer to partially surrounding or partially filling the described elements or layers, for example, with voids or spaces throughout. In contrast, when elements or layers are described as “entirely” or “completely” surrounded or filled, no voids or spaces may be present.

Specifically, a first low concentration doped region 250_1 may be disposed within the active region 212 along the outer wall of the first recess 231R_1. For example, the first low concentration doped region 250_1 may entirely surround a pair of outer walls 231R_1S1 and 231R_1S2 of the first recess 231R_1, which are opposite to one another in the second horizontal direction (Y direction). The first low concentration doped region 250_1 may include a part disposed between the first recess 231R_1 and the device isolation trench 221T. For example, a part of the first low concentration doped region 250_1 disposed within the active region 212 along the outer wall of the first recess 231R_1 may be located at a lower vertical level (e.g., relative to an upper surface of the substrate 210 on which the gate electrodes 242 are provided) than the part disposed between the first recess 231R_1 and the device isolation trench 221T.

Specifically, a second low concentration doped region 250_2 may be disposed within the active region 212 along the outer walls of the second recess 231R_2 and the third recess 231R_3. For example, the second low concentration doped region 250_2 may entirely surround a pair of outer walls of the second recess 231R_2 that are opposite to one another in the second horizontal direction (Y direction). For example, the second low concentration doped region 250_2 may entirely surround a pair of outer walls of the third recess 231R_3 that are opposite to one another in the second horizontal direction (Y direction). The second low concentration doped region 250_2 may include a part disposed between the second recess 231R_2 and the third recess 231R_3. For example, a part of the second low concentration doped region 250_2 disposed within the active region 212 along the outer walls of the second recess 231R_2 and the third recess 231R_3 may be located at a lower vertical level than the part disposed between the second recess 231R_2 and the third recesses 231R_3.

Specifically, a third low concentration doped region 250_3 may be disposed within the active region 212 along the outer wall of the fourth recess 231R_4. For example, the third low concentration doped region 250_3 may entirely surround a pair of outer walls of the fourth recess 231R_4 that are opposite to one another in the second horizontal direction (Y direction). The third low concentration doped region 250_3 may include a part disposed between the fourth recess 231R_4 and the device isolation trench 221T. For example, a part of the third low concentration doped region 250_3 disposed within the active region 212 along the outer wall of the fourth recess 231R_4 may be located at a lower vertical level than the part between the fourth recess 231R_4 and the device isolation trench 221T.

In some embodiments, the plurality of low concentration doped regions 250 may include a part overlapping the gate electrode 242 in the vertical direction (Z direction). For example, the first low concentration doped region 250_1 may include a part overlapping the first gate electrode 242_1 in the vertical direction (Z direction). For example, the second low concentration doped region 250_2 may include a part overlapping the first gate electrode 242_1 in the vertical direction (Z direction). For example, the second low concentration doped region 250_2 may include a part overlapping the second gate electrode 242_2 in the vertical direction (Z direction). For example, the third low concentration doped region 250_3 may include a part overlapping the second gate electrode 242_2 in the vertical direction (Z direction). Differently from what is shown, the plurality of low concentration doped regions 250 may not include the part overlapping the gate electrodes 242 in the vertical direction (Z direction).

In some embodiments, a plurality of source/drain regions 260 may be disposed buried within the plurality of low concentration doped regions 250. Specifically, each of the plurality of source/drain regions 260 may be disposed within the low concentration doped region 250 between each of the pair of gate electrodes 242_1 and 242_2 and the device isolation trench 221T, and between the pair of gate electrodes 242_1 and 242_2. In some embodiments, the plurality of source/drain regions 260 may be respectively doped with greater concentration of impurities than the plurality of low concentration doped regions 250. In some embodiments, the plurality of source/drain regions 260 may be respectively doped with the same conductivity type of impurities as the plurality of low concentration doped regions 250, which may be of the opposite conductivity type than the substrate 210.

Specifically, a first source/drain region 260_1 may be disposed in the first low concentration doped region 250_1. The first source/drain region 260_1 may be disposed in the first low concentration doped region 250_1 between the first gate electrode 242_1 and the device isolation trench 221T. The first source/drain region 260_1 may be disposed in the first low concentration doped region 250_1 between the first recess 231R_1 and the device isolation trench 221T. For example, the first source/drain region 260_1 may be doped with a greater concentration of impurities than the first low concentration doped region 250_1. For example, the first source/drain region 260_1 may be doped with the same conductivity type of impurities as the first low concentration doped region 250_1.

Specifically, a second source/drain region 260_2 may be disposed in the second low concentration doped region 250_2. The second source/drain region 260_2 may be disposed in the second low concentration doped region 250_2 between the first gate electrode 242_1 and the second gate electrode 242_2. The second source/drain region 260_2 may be disposed in the second low concentration doped region 250_2 between the second recess 231R_2 and the third recess 231R_3. In some embodiments, the second source/drain region 260_2 may be shared by respective transistors defined by the first gate structure 240_1 and the second gate structure 240_2, that is, such that the respective transistors defined by the gate structures 240_1 and 240_2 are electrically connected in series. For example, the second source/drain region 260_2 may be doped with a greater concentration of impurities than the second low concentration doped region 250_2. For example, the second source/drain region 260_2 may be doped with the same conductivity type of impurities as the second low concentration doped region 250_2.

Specifically, a third source/drain region 260_3 may be disposed in the third low concentration doped region 250_3. The third source/drain region 260_3 may be disposed in the third low concentration doped region 250_3 between the second gate electrode 242_2 and the device isolation trench 221T. The third source/drain region 260_3 may be disposed in the third low concentration doped region 250_3 between the fourth recess 231R_4 and the device isolation trench 221T. For example, the third source/drain region 260_3 may be doped with a greater concentration of impurities than the third low concentration doped region 250_3. For example, the third source/drain region 260_3 may be doped with the same conductivity type of impurities as the third low concentration doped region 250_3.

In some embodiments, the first low concentration doped region 250_1, the second low concentration doped region 250_2, and the third low concentration doped region 250_3 may include a first conductivity type of impurities having a first concentration. In some embodiments, the first source/drain region 260_1, the second source/drain region 260_2, and the third source/drain region 260_3 may include the first conductivity type of impurities having a second concentration greater than the first concentration. On the other hand, the active region 212 of the substrate 210 may include a second conductivity type of impurities different from the first conductivity type. For example, when the first low concentration doped region 250_1, the second low concentration doped region 250_2, and the third low concentration doped region 250_3 are n-doped, the first source/drain region 260_1, the second source/drain region 260_2 and the third source/drain region 260_3 may be n+ doped. For example, when the first low concentration doped region 250_1, the second low concentration doped region 250_2, and the third low concentration doped region 250_3 are n-doped, the active region 212 of the substrate 210 may be p-doped. This is the same in the opposite case.

In some embodiments, a depth D1 of the device isolation trench 221T may be greater than a depth D2 of the plurality of recesses 231R. The depths D1 and D2 of the device isolation trenches 221T and each of the plurality of recesses 231R may refer to distances from upper surfaces of the device isolation layer 221 and the insulating pattern 231 respectively disposed inside the device isolation trench 221T and the plurality of recesses 231R to bottom surfaces of the device isolation trenches 221T and the plurality of recesses 231R, along the vertical direction (e.g., the Z direction). The upper surfaces of the device isolation layer 221 and the insulating pattern 231 (and the upper portions or openings of the device isolation trench 221T and the plurality of recesses 231R) may be coplanar with (also referred to as having a same vertical level as) the upper surface of the substrate 210 on which the gate electrodes 242 are provided. For example, the upper surfaces of the device isolation layer 221 disposed in the device isolation trench 221T and the insulating pattern 231 disposed in the plurality of recesses 231R may be located at the same vertical level relative to the upper surface of the substrate 210. The depths D1 and D2 of the device isolation trenches 221T and each of the plurality of recesses 231R may refer to distances from an upper surface of the substrate 210 to the bottom surfaces of the device isolation trenches 221T and the plurality of recesses 231R. For example, the upper surface of the substrate 210 may be located at the same vertical level as the upper surfaces of the device isolation layer 221 and the insulating pattern 231.

Specifically, the depth D2 of each of the plurality of recesses 231R may be about 400 nm or less. Specifically, the depth D1 of the device isolation trench 221T may be about 1000 nm or more. In some embodiments, the depth D1 of the device isolation trench 221T may be more than two times, or about three times or more than, the depth D2 of each of the plurality of recesses 231R. For example, the depth D1 of the device isolation trench 221T may be about 1250 nm or more.

In some embodiments, a width of the device isolation trench 221T may be larger than a width of each of the plurality of recesses 231R along a horizontal direction (e.g., the second horizontal or Y direction). Specifically, in the second horizontal direction, the width of the device isolation trench 221T may be larger than the width of each of the plurality of recesses 231R at the same vertical level in the vertical or Z direction. For example, a width W1 of the device isolation trench 221T may be greater than a width W2 of each of the plurality of recesses 231R at a first vertical level LV1.

In some embodiments, a source/drain contact 270 configured to apply a voltage to each of the plurality of source/drain regions 260 may be disposed on each of the plurality of source/drain regions 260.

Specifically, a first source/drain contact 270_1 configured to apply a voltage to the first source/drain region 260_1 may be disposed on the first source/drain region 260_1. Specifically, a second source/drain contact 270_2 configured to apply a voltage to the second source/drain region 260_2 may be disposed on the second source/drain region 260_2. In some embodiments, the second source/drain contact 270_2 may be configured to be shared by the first gate structure 240_1 and the second gate structure 240_2. Specifically, a third source/drain contact 270_3 configured to apply a voltage to the third source/drain region 260_3 may be disposed on the third source/drain region 260_3.

The non-volatile memory device according to some embodiments includes the device isolation trench 221T having the depth D1 greater than the depth D2 of each of the plurality of recesses 231R, thereby improving a phenomenon in which current flowing along the plurality of low concentration doped regions 250 surrounding the plurality of recesses 231R flows to adjacent devices beyond the device isolation layer 221. That is, the non-volatile memory devices 10 and 100 including the transistor TR1 with improved performance and reliability may be provided according to some embodiments.

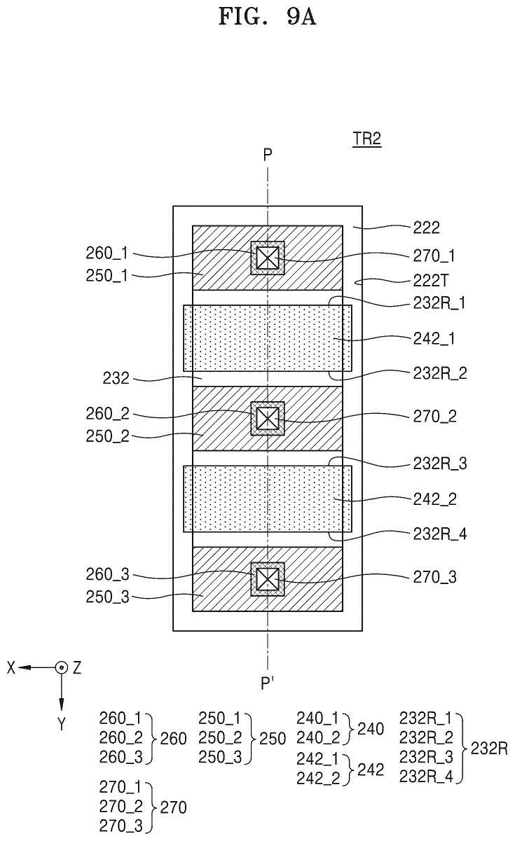

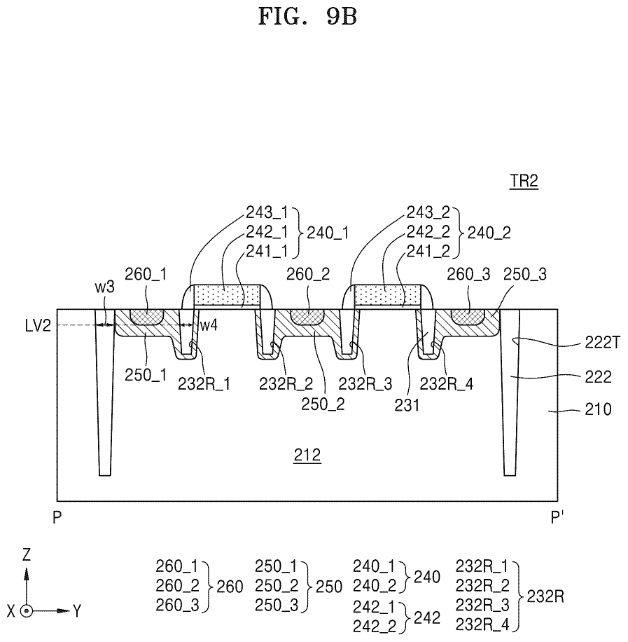

FIGS. 9A and 9B are plan and cross-sectional views illustrating a transistor TR2 included in a non-volatile memory device according to another embodiment.

Specifically, FIGS. 9A and 9B may be diagrams illustrating the transistor TR included in the non-volatile memory devices 10 and 100 described above. FIGS. 9A and 9B may illustrate one transistor TR2 among the transistors TR included in the peripheral circuit (e.g., 30 in FIG. 1) in the peripheral circuit structure PCS of the non-volatile memory devices 10 and 100 described above. In FIGS. 9A and 9B, the same descriptions as in FIGS. 8A and 8B are briefly given or omitted.

FIG. 9A is the plan view of the transistor TR2 according to an embodiment, and FIG. 9B is the cross-sectional view taken along line P-P′ of FIG. 9A.

Referring to FIGS. 9A and 9B, a device isolation layer 222 may be disposed on the substrate 210. A pair of gate structures 240 may be spaced apart from each other in the second horizontal direction (Y direction) on the active region 212 defined by the device isolation layer 222.

In some embodiments, a plurality of recesses 232R may be disposed in the active region 212 on both sides of the pair of gate electrodes 242. In some embodiments, the plurality of recesses 232R may be arranged adjacent to both sides of the pair of gate electrodes 242 in the second horizontal direction (Y direction).

Specifically, a first recess 232R_1 and a second recess 232R_2 may be disposed in the active region 212 adjacent to both sides of the first gate electrode 242_1. The first recess 232R_1 and the second recess 232R_2 may be spaced apart from each other in the second horizontal direction (Y direction). Specifically, a third recess 232R_3 and a fourth recess 232R_4 may be disposed in the active region 212 adjacent to both sides of the second gate electrode 242_2. The third recess 232R_3 and the fourth recess 232R_4 may be spaced apart from each other in the second horizontal direction (Y direction).

In some embodiments, the plurality of low concentration doped regions 250 may be respectively disposed along outer walls of the plurality of recesses 232R. Specifically, the plurality of low concentration doped regions 250 respectively surrounding the plurality of recesses 232R may be disposed in the active region 212 defined by the device isolation layer 222.

In some embodiments, the plurality of source/drain regions 260 may be disposed buried within the plurality of low concentration doped regions 250.

In some embodiments, a width of a device isolation trench 222T may be the same as a width of each of the plurality of recesses 232R along a horizontal direction (e.g., the second horizontal or Y direction). Specifically, in the second horizontal direction, the width of the device isolation trench 222T may be the same as the width of each of the plurality of recesses 232R at the same vertical level in the vertical or Z direction. For example, a width W3 of the device isolation trench 222T may be the same as a width W4 of each of the plurality of recesses 232R at a second vertical level LV2.

That is, the non-volatile memory devices 10 and 100 including the transistor TR2 with improved performance and reliability may be provided according to some embodiments.

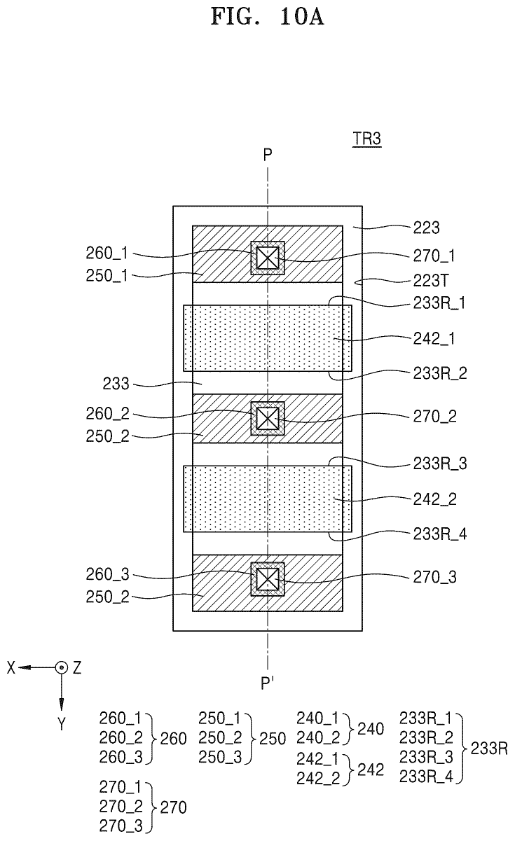

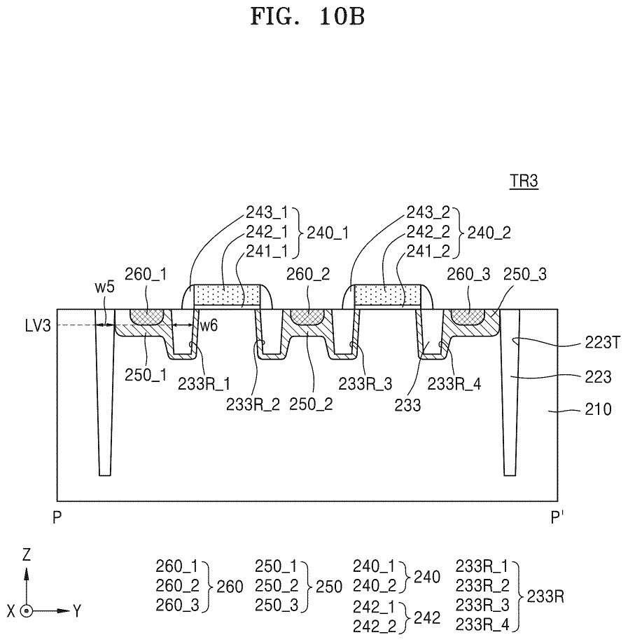

FIGS. 10A and 10B are plan and cross-sectional views illustrating a transistor TR3 included in a non-volatile memory device according to another embodiment.

Specifically, FIGS. 10A and 10B may be diagrams illustrating the transistor TR included in the non-volatile memory devices 10 and 100 described above. FIGS. 10A and 10B may illustrate one transistor TR3 among the transistors TR included in the peripheral circuit (e.g., 30 in FIG. 1) in the peripheral circuit structure PCS of the non-volatile memory devices 10 and 100 described above. In FIGS. 10A and 10B, the same descriptions as in FIGS. 8A and 8B are briefly given or omitted.

FIG. 10A is the plan view of the transistor TR3 according to an embodiment, and FIG. 10B is the cross-sectional view taken along line P-P′ of FIG. 10A.

Referring to FIGS. 10A and 10B, a device isolation layer 223 may be disposed on the substrate 210. A pair of gate structures 240 may be spaced apart from each other in the second horizontal direction (Y direction) on the active region 212 defined by the device isolation layer 223.

In some embodiments, a plurality of recesses 233R may be disposed in the active region 212 on both sides of the pair of gate electrodes 242. In some embodiments, the plurality of recesses 233R may be arranged adjacent to both sides of the pair of gate electrodes 242 in the second horizontal direction (Y direction).

Specifically, a first recess 233R_1 and a second recess 233R_2 may be disposed in the active region 212 adjacent to both sides of the first gate electrode 242_1. The first recess 233R_1 and the second recess 233R_2 may be spaced apart from each other in the second horizontal direction (Y direction). Specifically, a third recess 233R_3 and a fourth recess 233R_4 may be disposed in the active region 212 adjacent to both sides of the second gate electrode 242_2. The third recess 233R_3 and the fourth recess 233R_4 may be spaced apart from each other in the second horizontal direction (Y direction).

In some embodiments, the plurality of low concentration doped regions 250 may be respectively disposed along outer walls of the plurality of recesses 233R. Specifically, the plurality of low concentration doped regions 250 respectively surrounding the plurality of recesses 233R may be disposed in the active region 212 defined by the device isolation layer 223.

In some embodiments, the plurality of source/drain regions 260 may be disposed buried within the plurality of low concentration doped regions 250.

In some embodiments, a width of the device isolation trench 223T may be less than a width of each of the plurality of recesses 233R along a horizontal direction (e.g., the second horizontal or Y direction). Specifically, in the second horizontal direction, the width of the device isolation trench 223T may be less than the width of each of the plurality of recesses 233R at the same vertical level in the vertical or Z direction. For example, a width W5 of the device isolation trench 223T may be less than a width W6 of each of the plurality of recesses 233R at a third vertical level LV3.

That is, the non-volatile memory devices 10 and 100 including the transistor TR3 with improved performance and reliability may be provided according to some embodiments.

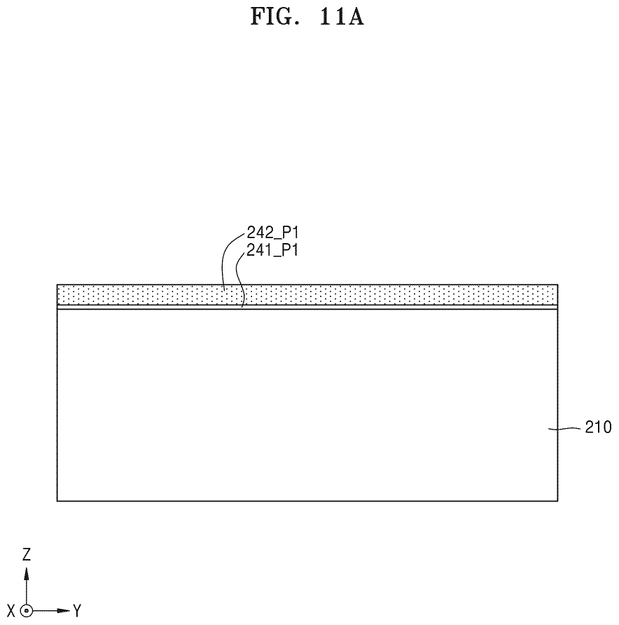

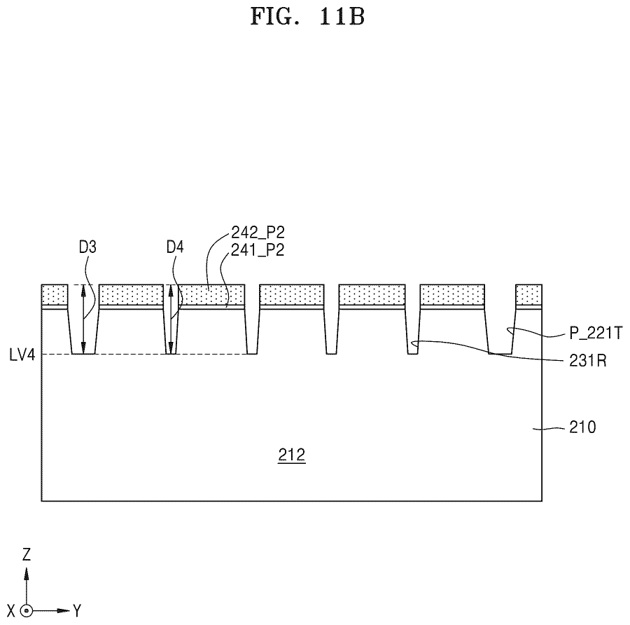

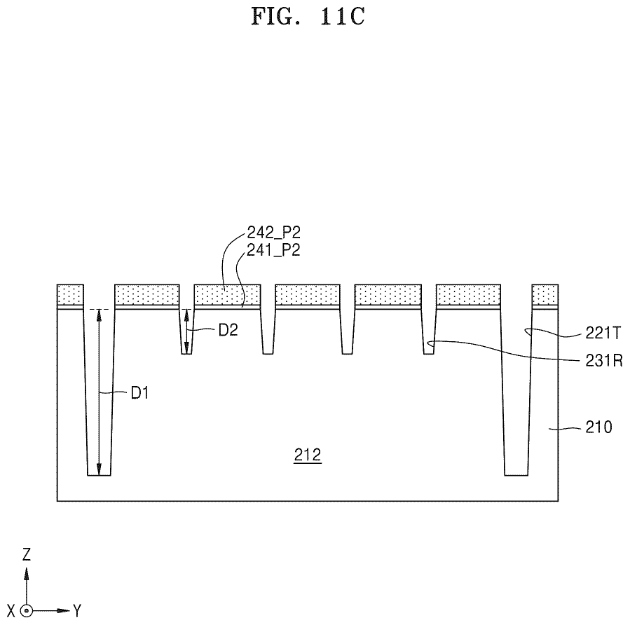

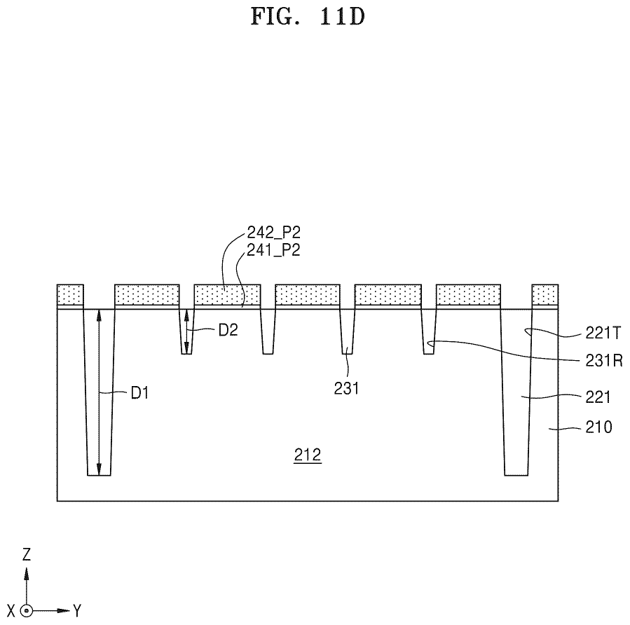

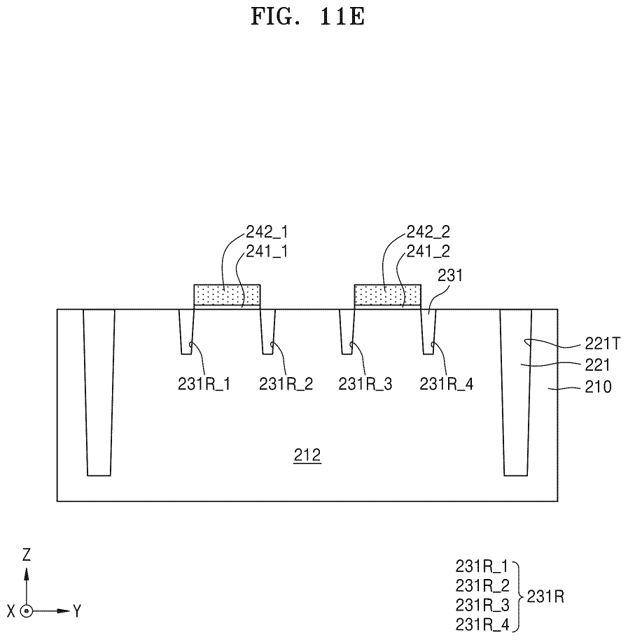

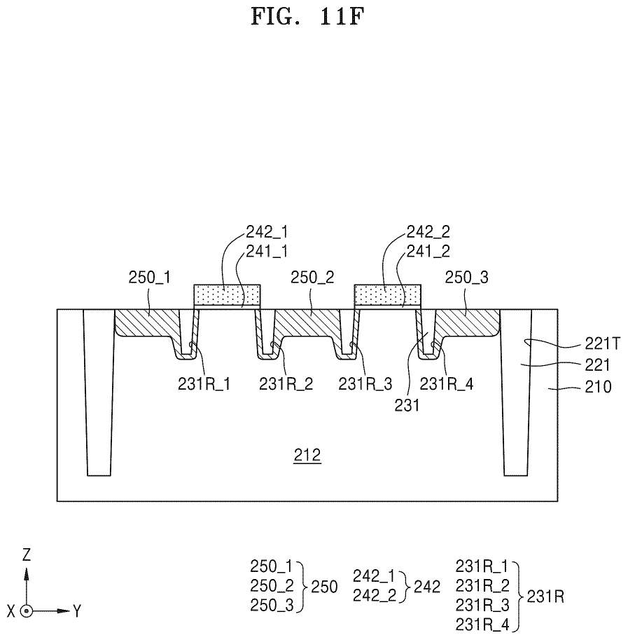

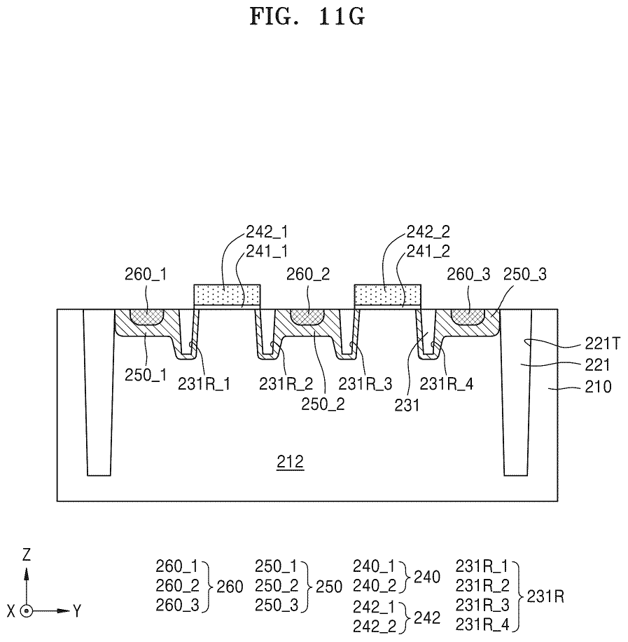

FIGS. 11A to 11G are cross-sectional views illustrating a method of manufacturing the transistor TR1 included in a non-volatile memory device according to an embodiment. Specifically, FIGS. 11A to 11G are cross-sectional views illustrating the method of manufacturing the transistor TR1 described with reference to FIGS. 8A and 8B.

Referring to FIG. 11A, a first pre-gate dielectric layer 241_P1 and a first pre-gate dielectric layer 242_P1 may be formed on the substrate 210.

Referring to FIG. 11B, the plurality of recesses 231R and a pre-device isolation trench P_221T may be formed by etching the first pre-gate layer 242_P1, the first pre-gate dielectric layer 241_P1, and the substrate 210. Through the process above, a second pre-gate layer 242_P2 and a second pre-gate dielectric layer 241_P2 may be formed. The etching process may be performed using a dry etching process. The active region 212 having a second conductivity type may be defined by the pre-device isolation trench P_221T.

In some embodiments, the plurality of recesses 231R and the pre-device isolation trench P_221T may have the same depth. Specifically, a distance D4 from an upper surface of the second pre-gate layer 242_P2 to a bottom surface of each of the plurality of recesses 231R and a distance D3 from an upper surface of the second pre-gate layer 242_P2 to a bottom surface of the pre-device isolation trench P_221T may be the same as each other. For example, the bottom surface of each of the plurality of recesses 231R and the bottom surface of the pre-device isolation trench P_221T may be located at a same vertical level LV4.

Referring to FIG. 11C, the device isolation trench 221T may be formed by further etching the substrate 210 exposed by the bottom surface of the pre-device isolation trench P_221T. Specifically, the etching process may be performed on the pre-device isolation trench P_221T by covering a part of a resultant of FIG. 11B excluding the pre-device isolation trench P_221T, particularly a part including the plurality of recesses 231R. Through the etching process, the device isolation trench 221T having a greater depth than that of each of the plurality of recesses 231R may be formed. The etching process may be performed using a dry etching process. The active region 212 may be defined by the device isolation trench 221T.

In some embodiments, the depth D1 of the device isolation trench 221T may be greater than the depth D2 of each of the plurality of recesses 231R. Specifically, the distance D1 from the upper surface of the substrate 210 to the bottom surface of the device isolation trench 221T may be greater than the distance D2 from the upper surface of the substrate 210 to the bottom surface of each of the plurality of recesses 231R. An ion implantation (IIP) process may not be performed to implant dopants (e.g., boron) into a bottom surface of the device isolation trench 221T.

As described above, the depth D2 of each of the plurality of recesses 231R may be about 400 nm or less. Specifically, the depth D1 of the device isolation trench 221T may be about 1000 nm or more. In some embodiments, the depth D1 of the device isolation trench 221T may be more than two times, or about three times or more than, the depth D2 of each of the plurality of recesses 231R. For example, the depth D1 of the device isolation trench 221T may be about 1250 nm or more.

Referring to FIG. 11D, the insulating pattern 231 filling each of the plurality of recesses 231R and the device isolation layer 221 filling the device isolation trench 221T may be formed. Processes of forming the insulating pattern 231 and the device isolation layer 221 may be performed simultaneously. The insulating pattern 231 and the device isolation layer 221 may each include silicon oxide.

In some embodiments, the distance D1 from the upper surface of the device isolation layer 221 to the bottom surface of the device isolation trench 221T may be greater than the distance D2 from the upper surface of the insulating pattern 231 to the bottom surface of each of the plurality of recesses 231R.

Referring to FIG. 11E, a pair of gate dielectric layers 241_1 and 241_2 and a pair of gate electrodes 242_1 and 242_2 may be formed by partially removing the second pre-gate layer 242_P2 and the second pre-gate dielectric layer 241_P2. In some embodiments, the plurality of recesses 231R may be disposed in the active region 212 on both sides (e.g., on opposing sides) of the pair of gate electrodes 242_1 and 242_2.

In some embodiments, the first recess 231R_1 and the second recess 231R_2 may be disposed in the active region 212 adjacent to both sides of the first gate electrode 242_1. In some embodiments, the third recess 231R_3 and the fourth recess 231R_4 may be disposed in the active region 212 adjacent to both sides of the second gate electrode 242_2.

Referring to FIG. 11F, the plurality of low concentration doped regions 250 may be respectively formed along outer walls of the plurality of recesses 231R. The low concentration doped regions 250 may extend to respective depths that are greater than the respective depths D2 of the recesses 231R, but less than the depth D1 of the device isolation trench 221T.

Specifically, the first low concentration doped region 250_1 may be formed within the active region 212 along (and extending to a depth beyond) the outer wall of the first recess 231R_1. The second low concentration doped region 250_2 may be formed within the active region 212 along (and extending to depths beyond) the outer walls of the second recess 231R_2 and the third recess 231R_3. The third low concentration doped region 250_3 may be formed within the active region 212 along (and extending to a depth beyond) the outer wall of the fourth recess 231R_4.

Referring to FIG. 11G, the plurality of source/drain regions 260 respectively buried within the plurality of low concentration doped regions 250 may be formed.

Specifically, the first source/drain region 260_1 may be formed in the first low concentration doped region 250_1. The second source/drain region 260_2 may be formed in the second low concentration doped region 250_2. The third source/drain region 260_3 may be formed in the third low concentration doped region 250_3.

Subsequently, the source/drain contact 270 configured to apply a voltage to each of the plurality of source/drain regions 260 may be formed on each of the plurality of source/drain regions 260.

The transistor TR1 may be completed by performing the above-described processes.

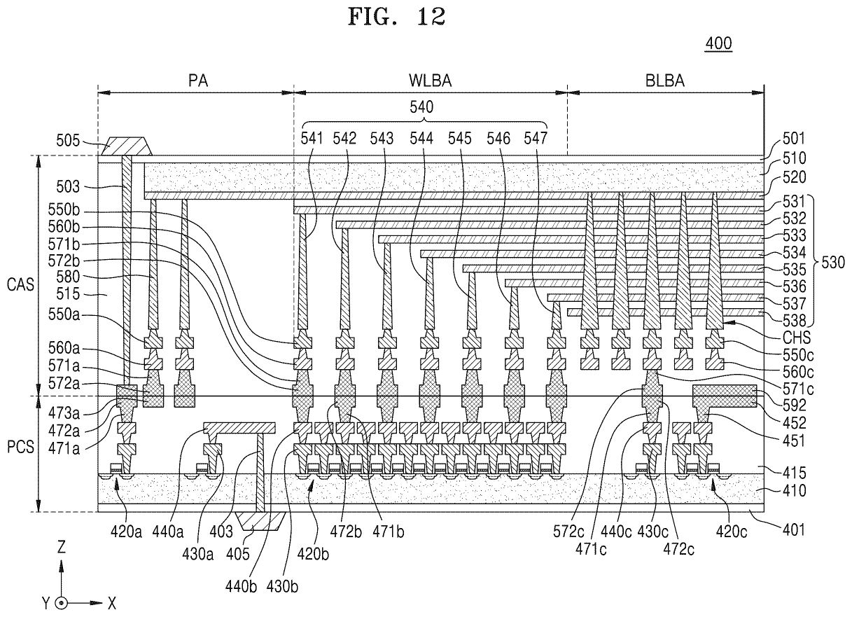

FIG. 12 is a cross-sectional view illustrating a non-volatile memory device 400 according to an embodiment.

Specifically, the non-volatile memory device 400 may have a chip to chip (C2C) structure. The C2C structure may mean manufacturing an upper chip including the cell array structure CAS on a first wafer, manufacturing a lower chip having the peripheral circuit structure PCS including a peripheral circuit on a second wafer different from the first wafer, and then connecting the upper chip and the lower chip to each other by a bonding method.

For example, the bonding method may refer to a method of electrically connecting a bonding metal formed on the uppermost metal layer of the upper chip and a bonding metal formed on the uppermost metal layer of the lower chip. For example, when the bonding metal includes copper (Cu), the bonding method may be a Cu—Cu bonding method, and the bonding metal may also include aluminum (Al) or tungsten (W).

Although FIG. 12 illustrates bonding one cell array structure CAS on the peripheral circuit structure PCS, upper chips including a plurality of cell array structures may also be bonded on the peripheral circuit structure PCS.

Each of the peripheral circuit structure PCS and the cell array structure CAS of the non-volatile memory device 400 may include an external pad bonding area PA, a word line bonding area WLBA, and a bit line bonding area BLBA.

The peripheral circuit structure PCS may include a first substrate 410, an interlayer insulating layer 415, a plurality of circuit devices 420a, 420b, and 420c formed on the first substrate 410, first metal layers 430a, 430b, and 430c respectively connected to the plurality of circuit devices 420a, 420b, and 420c, and second metal layers 440a, 440b, and 440c respectively formed on the first metal layers 430a, 430b, and 430c.

The circuit devices 420a, 420b, and 420c may include the transistors TR1 in FIGS. 8A to 8B, TR2 in FIGS. 9A to 9B, and TR3 in FIGS. 10A to 10B described above. In an embodiment, the first metal layers 430a, 430b, and 430c may each include tungsten having a relatively high resistivity, and the second metal layers 440a, 440b, and 440c may each include copper having a relatively low resistivity.

In this specification, only the first metal layers 430a, 430b, and 430c and the second metal layers 440a, 440b, and 440c are shown and described, but are not limited thereto, and at least one or more metal layers may be further formed on the second metal layers 440a, 440b, and 440c. At least some of the one or more metal layers formed on upper portions of the second metal layers 440a, 440b, and 440c may include aluminum, etc., having a lower resistivity than that of the copper of the second metal layers 440a, 440b, and 440c.

The interlayer insulating layer 415 may be disposed on the first substrate 410 to cover the plurality of circuit devices 420a, 420b, and 420c, the first metal layer 430a, 430b, and 430c, and the second metal layer 440a, 440b, and 440c, and may include an insulating material such as silicon oxide, silicon nitride, etc.

Lower bonding metals 471b and 472b may be formed on the second metal layer 440b of the word line bonding area WLBA. In the word line bonding area WLBA, the lower bonding metals 471b and 472b of the peripheral circuit structure PCS may be electrically connected to the upper bonding metals 571b and 572b of the cell array structure CAS respectively by a bonding method. The lower bonding metals 471b and 472b and the upper bonding metals 571b and 572b may each include aluminum, copper, or tungsten.

The cell array structure CAS may provide at least one block of memory cells. The cell array structure CAS may include a second substrate 510 and a common source line 520. On the second substrate 510, a plurality of word lines 531 to 538; 530 may be stacked in a direction (Z-axis direction) perpendicular to an upper surface of the second substrate 510. String selection lines and a ground selection line may be disposed above and below word lines 530, respectively, and the plurality of word lines 530 may be disposed between the string selection lines and the ground selection line.

In the bit line bonding area BLBA, a channel structure CHS may extend in the direction (Z-axis direction) perpendicular to the upper surface of the second substrate 510 to penetrate the word lines 530, the string selection lines, and the ground selection line. The channel structure CHS may include a data storage layer, a channel layer, and a buried insulating layer, and the channel layer may be electrically connected to a first metal layer 550c and a second metal layer 560c. For example, the first metal layer 550c may be a bit line contact, and the second metal layer 560c may be a bit line. In an embodiment, the bit line may extend in a second direction (Y-axis direction) parallel to the upper surface of the second substrate 510.

In an embodiment, an area where the channel structure CHS and the second metal layer 560c are disposed may be defined as the bit line bonding area BLBA. The bit line 560c may be electrically connected to the circuit devices 420c in the peripheral circuit structure PCS of the bit line bonding area BLBA. For example, the bit line 560c may be connected to upper bonding metals 571c and 572c in the peripheral circuit structure PCS, and the upper bonding metals 571c and 572c may be connected to lower bonding metals 471c and 472c connected to the circuit devices 420c.

In the word line bonding area WLBA, the word lines 530 may extend in a first direction (X direction) parallel to the upper surface of the second substrate 510, and a plurality of cell contact plugs 541 to 547; 540. The word lines 530 and the cell contact plugs 540 may be connected to each other at pads provided by at least some of the word lines 530 extending to different lengths in the first direction (X direction). A first metal layer 550b and a second metal layer 560b may be sequentially connected to upper portions of the cell contact plugs 540 connected to the word lines 530. The cell contact plugs 540 may be connected to the peripheral circuit structure PCS through the upper bonding metals 571b and 572b of the cell array structure CAS and the lower bonding metals 471b and 472b of the peripheral circuit structure PCS in the word line bonding area WLBA. The cell contact plugs 540 may be electrically connected to the circuit devices 420b of the peripheral circuit structure PCS.

A common source line contact plug 580 may be disposed in the external pad bonding area PA. The common source line contact plug 580 may include a conductive material such as metal, metal compound, or polysilicon, and may be electrically connected to the common source line 520. A first metal layer 550a and a second metal layer 560a may be sequentially stacked on the common source line contact plug 580. For example, an area where the common source line contact plug 580, the first metal layer 550a, and the second metal layer 560a are disposed may be defined as the external pad bonding area PA.

Lower bonding metals 471a and 472a may be formed in the external pad bonding area PA. In the external pad bonding area PA, the lower bonding metals 471a and 472a of the peripheral circuit structure PCS may be electrically connected to the upper bonding metals 571a and 572a of the cell array structure CAS by a bonding method, and the lower bonding metals 471a and 472a and the upper bonding metals 571a and 572a may include aluminum, copper, or tungsten.

Meanwhile, input/output pads 405 and 505 may be disposed in the external pad bonding area PA. A lower insulating layer 401 covering a lower surface of the first substrate 410 may be formed on the lower portion of the first substrate 410, and a first input/output pad 405 may be formed on the lower insulating layer 401. The first input/output pad 405 may be connected to at least one of the plurality of circuit devices 420a, 420b, and 420c disposed on the peripheral circuit structure PCS through a first input/output contact plug 403, and may be separated from the first substrate 410 by the lower insulating layer 401. In addition, a side insulating layer may be disposed between the first input/output contact plug 403 and the first substrate 410 to electrically separate the first input/output contact plug 403 and the first substrate 410.

An upper insulating layer 501 covering the upper surface of the second substrate 510 may be formed on the second substrate 510, and a second input/output pad 505 may be disposed on the upper insulating layer 501. The second input/output pad 505 may be connected to at least one of the plurality of circuit devices 420a, 420b, and 420c disposed on the peripheral circuit structure PCS through the second input/output contact plug 503.

In some embodiments, the second substrate 510 and the common source line 520 may not be disposed in an area where the second input/output contact plug 503 is disposed. In addition, the second input/output pad 505 may not overlap the word lines 530 in the third direction (Z-axis direction). The second input/output contact plug 503 may be separated from the second substrate 510 in a direction parallel to the upper surface of the second substrate 510, and penetrate the interlayer insulating layer 515 of the cell array structure CAS to be connected to the input/output pad 505.

In some embodiments, the first input/output pad 405 and the second input/output pad 505 may be formed selectively. For example, the non-volatile memory device 400 may include only the first input/output pad 405 disposed on the upper portion of the first substrate 410, or may include only the second input/output pad 505 disposed on the upper portion of the second substrate 510. Alternatively, the non-volatile memory device 400 may include both the first input/output pad 405 and the second input/output pad 505.

In each of the external pad bonding area PA and the bit line bonding area BLBA included each of in the cell array structure CAS and the peripheral circuit structure PCS, a metal pattern of the uppermost metal layer may exist as a dummy pattern, or the uppermost metal layer may be empty.

The non-volatile memory device 400 may form lower metal patterns 472a and 473a having the same shape as the upper metal pattern 572a of the cell array structure CAS on the uppermost metal layer of the peripheral circuit structure PCS, in correspondence to the upper metal pattern 572a formed on the uppermost metal layer of the cell array structure CAS, in the external pad bonding area PA. The lower metal pattern 473a formed on the uppermost metal layer of the peripheral circuit structure PCS may not be connected to a separate contact in the peripheral circuit structure PCS. Similarly, the nonvolatile memory device 400 may form the upper metal pattern 572a having the same shape as the lower metal pattern 473a of the peripheral circuit structure PCS in the upper metal layer of the cell array structure CAS, in correspondence to the lower metal pattern 473a formed in the uppermost metal layer of the peripheral circuit structure PCS in the external pad bonding area PA.

Lower bonding metals 471b and 472b may be formed on the second metal layer 440b of the word line bonding area WLBA. In the word line bonding area WLBA, the lower bonding metals 471b and 472b of the peripheral circuit structure PCS may be electrically connected to the upper bonding metals 571b and 572b of the cell array structure CAS by a bonding method.

In addition, the nonvolatile memory device 400 may form an upper metal pattern 592 having the same shape as the lower metal pattern 452 of the peripheral circuit structure PCS in the uppermost metal layer of the cell array structure CAS, in correspondence to the lower metal pattern 452 formed on the uppermost metal layer of the peripheral circuit structure PCS, in the bit line bonding area BLBA. A contact may not be formed on the upper metal pattern 592 formed on the uppermost metal layer of the cell array structure CAS. The lower metal pattern 452 of the peripheral circuit structure PCS may be electrically connected to the circuit device 420c through the metal layer 451.

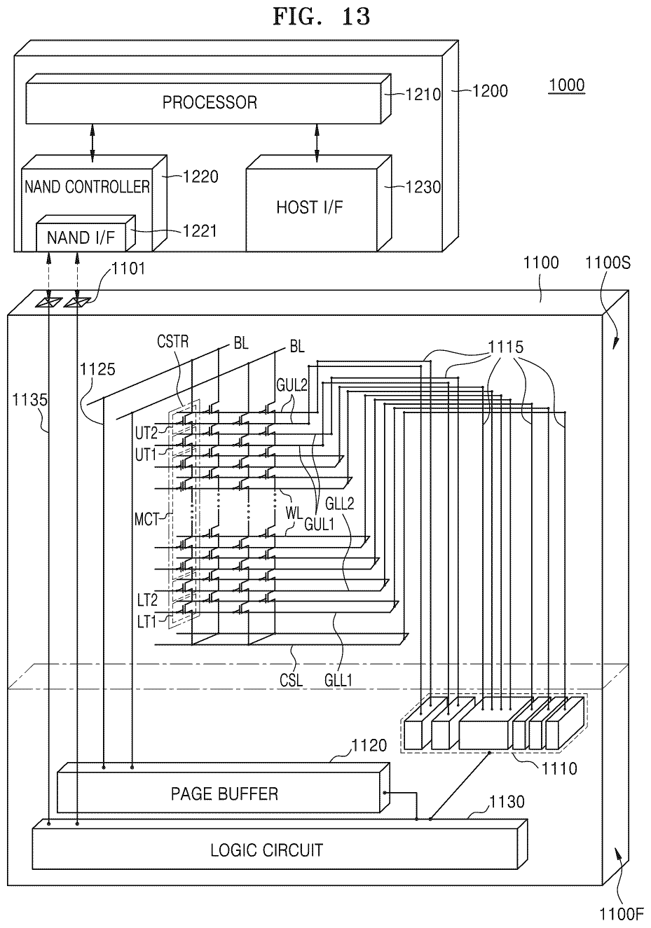

FIG. 13 is a diagram schematically illustrating an electronic system 1000 including a non-volatile memory device 1100 device according to an embodiment.

Specifically, the electronic system 1000 according to an embodiment may include the non-volatile memory device 1100 and a controller 1200 electrically connected to the non-volatile memory device 1100. The electronic system 1000 may be a storage device including one or a plurality of non-volatile memory devices 1100 or an electronic device including the storage device. The electronic system 1000 may be, for example, a solid state drive (SSD) device including at least one non-volatile memory device 1100, a universal serial bus (USB), a computing system, a medical device, or a communication device.

The non-volatile memory device 1100 may be a non-volatile semiconductor device. For example, the non-volatile memory device 1100 may be a NAND flash semiconductor device including at least one of the structures described above with respect to the non-volatile memory devices 100 and 400. The non-volatile memory device 1100 may include a first structure 1100F and a second structure 1100S on the first structure 1100F. In some embodiments, the first structure 1100F may be disposed next to the second structure 1100S. The first structure 1100F may be a peripheral circuit structure including a row decoder 1110, a page buffer 1120, and a logic circuit 1130. The second structure 1100S may be a memory cell structure including the bit line BL, the common source line CSL, the plurality of word lines WL, first and second gate upper lines GUL1 and GUL2, first and second gate lower lines GLL1 and GLL2, and a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT arranged between the lower transistors LT1 and LT2 and the upper transistors UT1 and UT2. The number of lower transistors LT1 and LT2 and the number of upper transistors UT1 and UT2 may be modified in various ways.

In some embodiments, the upper transistors UT1 and UT2 may include string select transistors, and the lower transistors LT1 and LT2 may include ground select transistors. The plurality of gate lower lines GLL1 and GLL2 may be gate electrodes of the lower transistors LT1 and LT2, respectively. The word line WL may be a gate electrode of the memory cell transistor MCT, and the gate upper lines GUL1 and GUL2 may be gate electrodes of the upper transistors UT1 and UT2.

The common source line CSL, the plurality of gate lower lines GLL1 and GLL2, the plurality of word lines WL, and the plurality of gate upper lines GUL1 and GUL2 may be electrically connected to the decoder circuit 1110 through a first connection wiring 1115 extending from the first structure 1100F to the second structure 1100S. The plurality of bit lines BL may be electrically connected to the page buffer 1120 through a plurality of second connection wirings 1125 extending from the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The non-volatile memory device 1100 may communicate with the controller 1200 through the input/output pad 1101 electrically connected to the logic circuit 1130. The input/output pad 1101 may be electrically connected to the logic circuit 1130 through an input/output connection wiring 1135 extending from the first structure 1100F to the second structure 1100S.

The controller 1200 may include a processor 1210, a NAND controller 1220, and a host interface 1230. According to some embodiments, the electronic system 1000 may include a plurality of semiconductor devices 1100, and, in this case, the controller 1200 may control the plurality of semiconductor devices 1100.

The processor 1210 may control overall operations of the electronic system 1000 including the controller 1200. The processor 1210 may operate according to a certain firmware, and may access the non-volatile memory device 1100 by controlling the NAND controller 1220. The NAND controller 1220 may include a NAND interface 1221 processing communication with the non-volatile memory device 1100. Through the NAND interface 1221, a control command for controlling the non-volatile memory device 1100, data to be written to the plurality of memory cell transistors MCT of the non-volatile memory device 1100, and data to be read from the plurality of memory cell transistors MCT of the non-volatile memory device 1100 may be transmitted. The host interface 1230 may provide a communication function between the electronic system 1000 and an external host. When receiving a control command from an external host through the host interface 1230, the processor 1210 may control the non-volatile memory device 1100 in response to the control command.

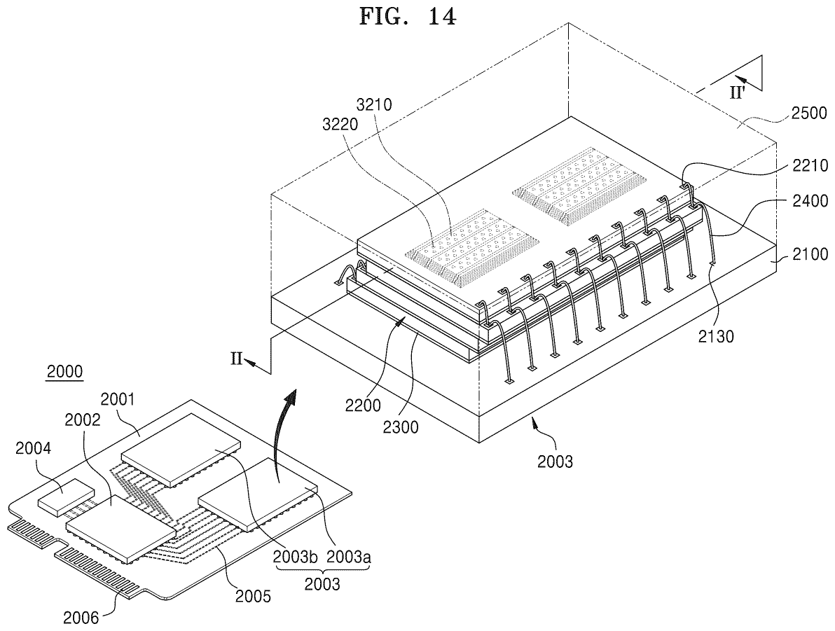

FIG. 14 is a perspective view schematically illustrating an electronic system 2000 including a non-volatile memory device according to an embodiment.

Specifically, the electronic system 2000 according to an embodiment may include a main board 2001, a controller 2002 mounted on the main board 2001, one or more semiconductor packages 2003, and a DRAM 2004. The semiconductor package 2003 and the DRAM 2004 may be connected to the controller 2002 by a plurality of wiring patterns 2005 formed on the main board 2001.

The main board 2001 may include a connector 2006 including a plurality of pins combined with an external host. The number and arrangement of the plurality of pins in the connector 2006 may vary depending on a communication interface between the electronic system 2000 and the external host. In some embodiments, the electronic system 2000 may communicate with the external host according to any one of interfaces such as Universal Serial Bus (USB), Peripheral Component Interconnect Express (PCI-Express), Serial Advanced Technology Attachment (SATA), M-Phy for Universal Flash Storage (UFS), etc. In some embodiments, the electronic system 2000 may operate by power supplied from the external host through the connector 2006. The electronic system 2000 may further include a power management integrated circuit (PMIC) distributing power supplied from the external host to the controller 2002 and the semiconductor package 2003.

The controller 2002 may write data to or read data from the semiconductor package 2003, and may improve the operating speed of the electronic system 2000.

The DRAM 2004 may be a buffer memory reducing a speed difference between the semiconductor package 2003 that is a data storage space, and the external host. The DRAM 2004 included in the electronic system 2000 may operate as a kind of cache memory, and may provide a space temporarily storing data in a control operation on the semiconductor package 2003. When the electronic system 2000 includes the DRAM 2004, the controller 2002 may further include a DRAM controller controlling the DRAM 2004, in addition to a NAND controller controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 arranged on a lower surface of each of the plurality of semiconductor chips 2200, a connection structure 2400 electrically connecting the plurality of semiconductor chips 2200 and the package substrate 2100, and a molding layer 2500 covering the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 13. Each of the plurality of semiconductor chips 2200 may include a plurality of gate stacks 3210 and a plurality of channel structures 3220. Each of the plurality of semiconductor chips 2200 may include at least one of the vertical non-volatile memory devices 100 and 400 described above.

In some embodiments, the connection structure 2400 may be a bonding wiring electrically connecting the input/output pad 2210 and the package upper pad 2130. Accordingly, in the first and second semiconductor packages 2003a and 2003b, the plurality of semiconductor chips 2200 may be electrically connected to each other by a bonding wiring method, and may be electrically connected to the package upper pad 2130 of the package substrate 2100. In some embodiments, in the first and second semiconductor packages 2003a and 2003b, the plurality of semiconductor chips 2200 may be electrically connected to each other by a connection structure including a through silicon via (TSV) instead of the bonding wiring type connection structure 2400.

In some embodiments, the controller 2002 and the plurality of semiconductor chips 2200 may be included in one package. In some embodiments, the controller 2002 and the plurality of semiconductor chips 2200 may be mounted on a separate interposer substrate different from the main board 2001, and the controller 2002 and the plurality of semiconductor chips 2200 may be connected to each other by a wiring formed on the interposer substrate.

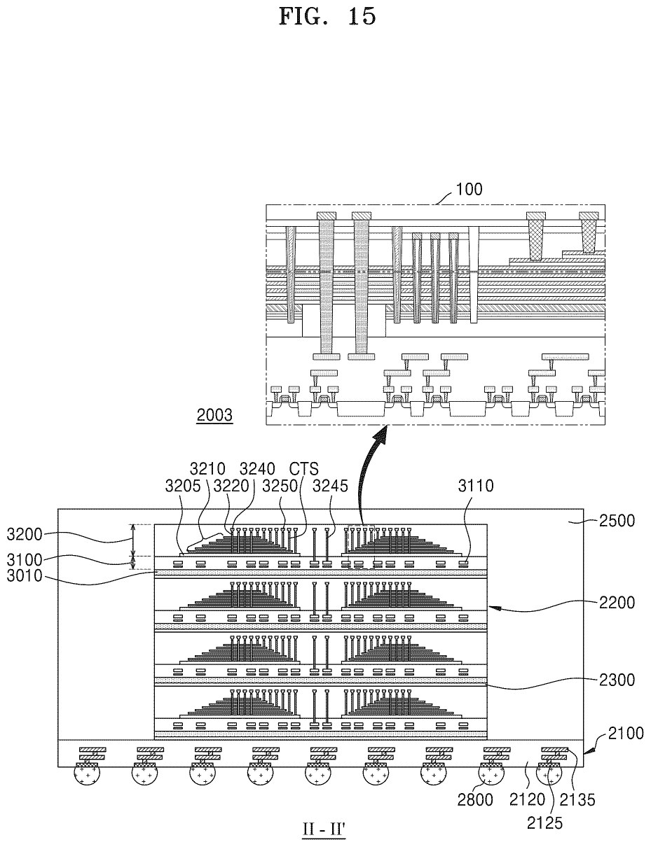

FIG. 15 is a cross-sectional view schematically illustrating the semiconductor package 2003 according to an embodiment. FIG. 15 is a detailed cross-sectional view taken along line II-II′ of FIG. 14.

Specifically, in a semiconductor package 2003, the package substrate 2100 may be a printed circuit board. The package substrate 2100 may include a package substrate body portion 2120, a plurality of package upper pads 2130 (see FIG. 14) arranged on an upper surface of the package substrate body portion 2120, a plurality of lower pads 2125 arranged on or exposed through a lower surface of the package substrate body portion 2120, and a plurality of internal wirings 2135 electrically connecting the plurality of package upper pads 2130 and the plurality of lower pads 2125 in the package substrate body portion 2120. The plurality of package upper pads 2130 may be electrically connected to the plurality of connection structures 2400. The plurality of lower pads 2125 may be connected to the plurality of wiring patterns 2005 on the main board 2001 of the electronic system 2000 shown in FIG. 14 through a plurality of conductive bumps 2800.

Each of the plurality of semiconductor chips 2200 may include a semiconductor substrate 3010 and a first structure 3100 and a second structure 3200 sequentially stacked on the semiconductor substrate 3010. The first structure 3100 may include a peripheral circuit region including a plurality of peripheral wirings 3110. The second structure 3200 may include a common source line 3205, a gate stack 3210 on the common source line 3205, a channel structure 3220 penetrating the gate stack 3210, and a bit line 3240 electrically connected to the channel structure 3220. In some embodiments, each of the plurality of semiconductor chips 2200 may include the same configuration as described with respect to the non-volatile memory devices 100 and 400 described above.

Each of the plurality of semiconductor chips 2200 may include a through wiring 3245 electrically connected to the plurality of peripheral wirings 3110 of the first structure 3100 and extending into the second structure 3200. The through wiring 3245 may be disposed outside the gate stack 3210. In some embodiments, the semiconductor package 2003 may further include a through wiring 3250 penetrating the gate stack 3210. Each of the plurality of semiconductor chips 2200 may further include input/output pads (2210 in FIG. 14) electrically connected to the plurality of peripheral wirings 3110 of the first structure 3100.

It will be understood that spatially relative terms such as ‘on,’ ‘upper,” upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

While the inventive concept has been particularly shown and described with reference to embodiments thereof, it will be understood that various changes in form and details may be made therein without departing from the scope of the following claims.

What is claimed is:

1. A non-volatile memory device comprising:
a peripheral circuit and a memory cell array that are sequentially stacked, wherein the peripheral circuit comprises:
a substrate including a device isolation layer in a device isolation trench therein defining an active region;
a first gate electrode extending in a first horizontal direction on the active region of the substrate;
an insulating pattern in a first recess and a second recess spaced apart in a second horizontal direction intersecting the first horizontal direction within the active region on opposing sides of the first gate electrode;
a first low concentration doped region within the substrate and extending along an outer wall of the first recess;
a second low concentration doped region within the substrate and extending along an outer wall of the second recess;
a first source/drain region buried in the first low concentration doped region between the first recess and the device isolation trench in the second horizontal direction; and
a second source/drain region buried in the second low concentration doped region between the second recess and the device isolation trench in the second horizontal direction,
wherein a depth of each of the first recess and the second recess is 400 nm or less, and
wherein a depth of the device isolation trench is 1000 nm or more but is less than a thickness of the substrate in a vertical direction.

2. The non-volatile memory device of claim 1, wherein:
the first low concentration doped region comprises a portion between the first recess and the device isolation trench; and
the second low concentration doped region comprises a portion between the second recess and the device isolation trench.

3. The non-volatile memory device of claim 1, wherein the first gate electrode comprises polysilicon.

4. The non-volatile memory device of claim 1, further comprising:
a first gate dielectric layer disposed the first gate electrode and the substrate.

5. The non-volatile memory device of claim 1, further comprising:
a first source/drain contact on the first source/drain doped region and configured to apply a voltage to the first source/drain region; and
a second source/drain contact on the second source/drain doped region and configured to apply a voltage to the second source/drain region.

6. The non-volatile memory device of claim 1, wherein:
the first low concentration doped region and the second low concentration doped region each comprises a first conductivity type of impurities having a first concentration;
the first source/drain region and the second source/drain region each comprises the first conductivity type of impurities having a second concentration greater than the first concentration; and
the substrate comprises a second conductivity type of impurities different from the first conductivity type.

7. The non-volatile memory device of claim 6, wherein:
the substrate comprises p-type impurities; and
the first low concentration doped region, the second low concentration doped region, the first source/drain region, and the second source/drain region each comprises n-type impurities.

8. The non-volatile memory device of claim 1, wherein the first recess and the device isolation trench have a same width in the second horizontal direction.

9. The non-volatile memory device of claim 1, further comprising:
a second gate extending in the first horizontal direction on the active region of the substrate and spaced apart from the first gate electrode in the second horizontal direction with the second recess and the second source/drain region therebetween;
a third recess and a fourth recess spaced apart in the second horizontal direction within the active region on opposing sides of the second gate electrode, the third recess being spaced apart from the second recess with the second source/drain region therebetween, and the fourth recess being spaced apart from the third recess with the second gate electrode therebetween;
a third low concentration doped region within the substrate along an outer wall of the fourth recess; and
a third source/drain region spaced apart from the second gate electrode in the second horizontal direction with the fourth recess therebetween, and buried in the third low concentration doped region between the fourth recess and the device isolation trench in the second horizontal direction,
wherein the second low concentration doped region further includes a portion in the substrate extending along an outer wall of the third recess, and
wherein the second source/drain region is between the second recess and the third recess and is shared by a first transistor and a second transistor defined by the first gate electrode and the second gate electrode.

10. The non-volatile memory device of claim 1, wherein the outer wall of the first recess comprises a first outer wall and a second outer wall, which are opposite to one another in the second horizontal direction, and wherein the first low concentration doped region surrounds the first outer wall and the second outer wall.

11. A non-volatile memory device comprising:
a peripheral circuit comprising a plurality of transistors, wherein the plurality of transistors comprise:
a pair of gate electrodes extending in a first horizontal direction on an active region defined by a device isolation layer in a substrate and spaced apart from each other in a second horizontal direction intersecting the first horizontal direction;
a plurality of low concentration doped regions respectively extending in the substrate along outer walls of a plurality of recesses on opposing sides of each of the pair of gate electrodes; and
a plurality of source/drain regions buried in the plurality of low concentration doped regions,
wherein the device isolation layer is in a device isolation trench extending around the pair of gate electrodes,
wherein a depth of each of the plurality of recesses is 400 nm or less, and
wherein a depth of the device isolation trench is 1000 nm or more but is less than a thickness of the substrate in a vertical direction.

12. The non-volatile memory device of claim 11, wherein each of the pair of gate electrodes comprises polysilicon.

13. The non-volatile memory device of claim 11, wherein the pair of gate electrodes comprises a first gate electrode and a second gate electrode, and
wherein the plurality of low concentration doped regions comprise:
a first low concentration doped region in the active region between the device isolation trench and the first gate electrode;
a second low concentration doped region in the active region between the first gate electrode and the second gate electrode; and
a third low concentration doped region in the active region between the second gate electrode and the device isolation trench.

14. The non-volatile memory device of claim 13, wherein the plurality of recesses comprise a first recess, a second recess, a third recess, and a fourth recess spaced apart from each other in the second horizontal direction, and
wherein the plurality of source/drain regions comprise:
a first source/drain region buried in the first low concentration doped region between the first recess and the device isolation trench;
a second source/drain region buried in the second low concentration doped region between the second recess and the third recess; and
a third source/drain region buried in the third low concentration doped region between the fourth recess and the device isolation trench.

15. The non-volatile memory device of claim 14, wherein the second source/drain region is shared by a first transistor and a second transistor defined by the first gate electrode and the second gate electrode.

16. The non-volatile memory device of claim 14, wherein:
the first low concentration doped region, the second low concentration doped region, and the third low concentration doped region each comprise a first conductivity type of impurities having a first concentration;
the first source/drain region, the second source/drain region, and the third source/drain region comprise the first conductivity type of impurities having a second concentration greater than the first concentration; and
the substrate comprises a second conductivity type of impurities different from the first conductivity type.

17. The non-volatile memory device of claim 14, further comprising:
a source/drain contact on the second source/drain region and configured to apply a voltage to the second source/drain region,
wherein the source/drain contact is shared by a first transistor and a second transistor defined by the first gate electrode and the second gate electrode.

18. The non-volatile memory device of claim 11, further comprising:
a plurality of insulating patterns respectively provided inside the plurality of recesses,
wherein the plurality of insulating patterns each include oxide.

19. A non-volatile memory device comprising:
a peripheral circuit comprising a plurality of transistors provided on a substrate; and
a memory cell array configured to be controlled by the peripheral circuit,
wherein the plurality of transistors comprise:
a first polysilicon electrode and a second polysilicon electrode extending in a first horizontal direction on an active region defined by a device isolation layer in the substrate and spaced apart from each other in a second horizontal direction intersecting the first horizontal direction;
a plurality of low concentration doped regions respectively provided in the substrate along outer walls of a plurality of recesses on opposing sides of each of the first polysilicon electrode and the second polysilicon electrode; and
a plurality of source/drain regions buried in the plurality of low concentration doped regions,
wherein the device isolation layer is in a device isolation trench extending around the first and second polysilicon electrodes,
wherein the plurality of low concentration doped regions comprise:
a first low concentration doped region between the device isolation trench and the first polysilicon electrode;
a second low concentration doped region between the first polysilicon electrode and the second polysilicon electrode; and
a third low concentration doped region spaced apart from the second low concentration doped region with the second polysilicon electrode therebetween,
wherein the plurality of recesses include a first recess, a second recess, a third recess, and a fourth recess spaced apart from each other in the second horizontal direction,
wherein the plurality of source/drain regions comprise:
a first source/drain region buried in the first low concentration doped region and spaced apart from the first polysilicon electrode with the first recess therebetween;
a second source/drain region buried in the second low concentration doped region, spaced apart from the first polysilicon electrode with the second recess therebetween, and spaced apart from the second polysilicon electrode with the third recess therebetween; and
a third source/drain region buried in the third low concentration doped region and spaced apart from the second polysilicon electrode with the fourth recess therebetween,
wherein a depth of each of the plurality of recesses is 400 nm or less, and
wherein a depth of the device isolation trench is 1000 nm or more but is less than a thickness of the substrate in a vertical direction.

20. The non-volatile memory device of claim 19, wherein the second source/drain region is shared by a first transistor and a second transistor defined by the first polysilicon electrode and the second polysilicon electrode.
